(19) United States
(12) Patent Application Publication
(10) Pub. No.: US 2025/0216783 A1
(43) Pub. Date: Jul. 3, 2025

(54) ANTI-SPACER MASKING PROCESS USING SECOND SWITCHABLE POLYMER

(71) Applicant: Tokyo Electron Limited, Tokyo (JP)

(72) Inventors: Phillip D. Hustad, Longmont, CO (US); Jordan B. Greenough, Schenectady, NY (US); Max J. Klemes, Schenectady, NY (US)

(21) Appl. No.: 18/988,644

(22) Filed: Dec. 19, 2024

Related U.S. Application Data
(60) Provisional application No. 63/616,073, filed on Dec. 29, 2023.

(51) Int. Cl. G03F 7/039; G03F 7/00; G03F 7/32

(52) U.S. Cl. CPC G03F 7/039; G03F 7/0035; G03F 7/322; G03F 7/325

(57) ABSTRACT

A method for forming a patterned mask includes providing first and second structures. The first structure includes a first material including a first polymer, and a first converted region of a second material extending into the first structure. The second material has been chemically transformed from the first material by a catalyst portion of a first solubility shifting agent diffused into the first converted region. The second structure includes a third material including a second polymer with a functional group protected by a protecting group, and has an overburden region overlying the first converted region. The method further includes chemically transforming the overburden region to a second converted region of a fourth material using a catalyst portion of a second solubility shifting agent. The first and third materials are insoluble in a developer containing a polar solvent and the second and fourth materials are soluble in the developer.

### CROSS-REFERENCE TO RELATED APPLICATIONS

This application claims the priority and benefit of U.S. Provisional Application No. 63/616,073, filed on Dec. 29, 2023, which application is hereby incorporated herein by reference in its entirety.

### TECHNICAL FIELD

The present disclosure relates generally to methods for forming an anti-spacer patterned mask, and more particularly, photolithography materials and processes in methods for forming an anti-spacer patterned mask during manufacturing of semiconductor devices.

### BACKGROUND

In photolithography for semiconductor manufacturing, a relief pattern can be topographical variation created on a surface of and/or through a photoresist material layer. A relief pattern can be formed when portions of a photoresist material layer are selectively exposed to light and then chemically developed, resulting in regions with different heights or levels, such as trenches and holes formed in and patterned in a layer or film of photoresist material. The photoresist material is a light-sensitive material that undergoes chemical changes when exposed to ultraviolet (UV) light or extreme ultraviolet (EUV) light (e.g., light with a wavelength of 13.5 nm). The photoresist material is typically exposed to a patterned light through a mask or directly using a laser. The pattern transferred to the photoresist material by exposure to light defines exposed areas and regions of the photoresist material.

In positive photoresist, the exposed regions become soluble and can be removed in a development process by chemicals of a developer solvent. In negative photoresist, the exposed regions become insoluble, and the unexposed areas can be removed in a development process by chemicals of a developer solvent. After exposure and pattern transfer, the wafer can be subjected to a chemical developer that dissolves the soluble parts of the photoresist to create a relief pattern on the surface of and/or through the photoresist material layer, such that the exposed (or unexposed) areas are removed, leaving behind patterned features. Then, this relief pattern can be used as a mask for further processing steps, such as etching or ion implantation, to transfer the pattern (design) into underlying layers and/or a substrate of the wafer.

In material processing methodologies (such as photolithography), creating patterned layers typically involves the application of a thin layer of radiation-sensitive material, such as photoresist, to an upper surface of a substrate. This radiation-sensitive material is transformed into a patterned mask that can be used to etch or transfer a pattern into an underlying layer on a substrate. Patterning of the radiation-sensitive material generally involves exposure by a radiation source through a reticle (and associated optics) onto the radiation-sensitive material using, for example, a photolithographic exposure system.

This exposure creates a latent pattern within the radiation-sensitive material which can then be developed. Developing refers to dissolving and removing a portion of the radiation-sensitive material to yield a relief pattern (topographic pattern). The portion of material removed can be either irradiated regions or non-irradiated regions of the radiation-sensitive material depending on a photoresist tone and/or type of developing solvent used. The relief pattern can then function as a mask layer defining a pattern.

Preparation and development of various films used for patterning can include thermal treatment (e.g. baking). For example, a newly applied film can receive a post-application bake (PAB) to evaporate solvents and/or to increase structural rigidity or etch resistance. Also, a post-exposure bake (PEB) can be executed to set a given pattern to prevent further dissolving. Fabrication tools for coating and developing substrates typically include one or more baking modules. Some photolithography processes include coating a substrate with a thin film of bottom anti-reflective coating (BARC), followed by coating with a resist, and then exposing the substrate to a pattern of light as a process step for creating microchips. A relief pattern created can then be used as a mask or template for additional processing such as transferring the pattern into an underlying layer.

The minimum resolution attainable with a single lithographic exposure is limited, amongst other things, by the wavelength of light used (the so-called diffraction limit). Techniques such as immersion lithography can be utilized to lower the diffraction limit. Multiple patterning processes such as Self-Aligned Double Patterning (SADP) are increasingly being used for scaling semiconductor features below photolithographic limits. Multiple patterning processes can double pitch (for each additional patterning) and thus help to achieve feature sizes that are otherwise unattainable.

However, multiple patterning processes are frequently costly and complex. Additionally, multiple patterning process flows can be incompatible with high volume manufacturing. Further, many multiple patterning techniques require additional process steps such as etching, deposition, development, and treatments which also increase complexity and reduce throughput. Therefore, multiple pattern processes that reduce cost, reduce complexity, and/or increase compatibility are desirable.

### SUMMARY

In an embodiment of the present disclosure, a method for forming a patterned mask includes providing a first intermediate structure on a substrate. The first intermediate structure includes a first material including a first polymer. The first intermediate structure further includes a first converted region of a second material to a first depth into the first intermediate structure. The second material has been chemically transformed from the first material by at least a catalyst portion of a first solubility shifting agent diffused into the first converted region. The first material is insoluble in a developer containing a polar solvent. The second material is soluble in the developer containing the polar solvent. The method further includes providing a second intermediate structure on the substrate. The second intermediate structure includes a third material including a second polymer with a functional group protected by a protecting group. The second intermediate structure includes an overburden region overlying the first converted region of the first intermediate structure. The third material is soluble in a solvent system that does not dissolve the first intermediate structure. The third material is insoluble in the developer containing the polar solvent. The method further includes providing at least a catalyst portion of a second solubility shifting agent to the overburden region of the second intermediate structure and chemically transforming the overburden region of the second intermediate structure to a second converted region of a fourth material using the catalyst portion of the second solubility shifting agent as a chemical reaction catalyst, such that the fourth material is soluble in the developer containing the polar solvent.

In an embodiment of the present disclosure, a method for forming a patterned mask includes providing a first intermediate structure on a substrate. The first intermediate structure includes a first material including a first polymer. The first intermediate structure further includes a first converted region of a second material to a first depth into the first intermediate structure. The second material has been chemically transformed from the first material by at least a catalyst portion of a first solubility shifting agent diffused into the first converted region. The first material is insoluble in an aqueous tetramethylammonium hydroxide (TMAH) developer. The second material is soluble in the aqueous TMAH developer. The method further includes providing a second intermediate structure on the substrate. The second intermediate structure includes a third material including a second polymer. The second polymer includes para-hydroxystyrene. A hydroxyl group of the para-hydroxystyrene is protected by a vinyl ether protecting group. The second intermediate structure includes an overburden region overlying the first converted region of the first intermediate structure. The third material is soluble in a solvent system that does not dissolve the first intermediate structure. The third material is insoluble in the an aqueous TMAH developer. The method further includes providing at least a catalyst portion of a second solubility shifting agent to the overburden region of the second intermediate structure and chemically transforming the overburden region of the second intermediate structure to a second converted region of a fourth material using the catalyst portion of the second solubility shifting agent as a chemical reaction catalyst, such that the fourth material is soluble in the aqueous TMAH developer.

In an embodiment of the present disclosure, a method for forming a patterned mask includes providing a patterned photoresist layer on a substrate and depositing an overcoat layer over the patterned photoresist layer and the substrate. The patterned photoresist layer includes a first material including a first polymer. The first material is insoluble in a developer containing a polar solvent. The overcoat layer includes a first solubility shifting agent. The method further includes diffusing at least a catalyst portion of the first solubility shifting agent from the overcoat layer into first regions of the patterned photoresist layer and chemically transforming the first regions of the patterned photoresist layer to anti-spacer regions of a second material to a first depth into the patterned photoresist layer, removing the overcoat layer leaving behind the patterned photoresist layer including the anti-spacer regions, and depositing an additional resist layer over the patterned photoresist layer. The second material is soluble in the developer containing the polar solvent. The additional resist layer includes a third material including a second polymer with a functional group protected by a protecting group. The additional resist layer includes overburden regions overlying the anti-spacer regions of the patterned photoresist layer. The third material is soluble in a solvent system that does not dissolve the patterned photoresist layer. The third material is insoluble in the developer containing the polar solvent. The method further includes chemically transforming the overburden regions of the additional resist layer to a soluble region of a fourth material using a chemical reaction catalyst, such that the fourth material is soluble in the developer containing the polar solvent, and removing the anti-spacer regions using the polar solvent of the developer to form an anti-spacer pattern including remaining portions of the first patterned photoresist layer and the additional resist layer, the anti-spacer pattern having openings to the substrate corresponding to the anti-spacer regions. At least part of the openings has a critical dimension corresponding to the first depth. The overburden regions are chemically transformed by diffusing at least a catalyst portion of the first solubility shifting agent as the chemical reaction catalyst from the anti-spacer regions of the first patterned photoresist layer into the overburden regions, and/or by generating a catalyst portion of a second solubility shifting agent in the overburden region of the second intermediate structure as the chemical reaction catalyst by activating the second solubility shifting agent.

### BRIEF DESCRIPTION OF THE DRAWINGS

For a more complete understanding of example embodiments of the present disclosure, and the advantages thereof, reference is now made to the following descriptions taken in conjunction with the accompanying drawings, in which:

FIGS. 1A to 1F are cross-section views illustrating intermediate structures in a method for forming a patterned mask according to an embodiment of the present disclosure;

FIG. 1G is a cross-section view illustrating an anti-spacer patterned mask formed using the method portrayed in FIGS. 1A to 1F, according to an embodiment of the present disclosure;

FIG. 1H is a cross-section view illustrating a substrate etched using the anti-spacer patterned mask formed using the method portrayed in FIGS. 1A to 1F, according to an embodiment of the present disclosure;

FIGS. 2A to 2C are cross-section views illustrating intermediate structures in a method for forming an anti-spacer patterned mask according to an embodiment of the present disclosure;

FIGS. 3A to 3C are cross-section views illustrating intermediate structures in a method for forming an anti-spacer patterned mask according to an embodiment of the present disclosure;

FIG. 4 is a schematic view illustrating a second polymer included in a second intermediate structure in a method for forming an anti-spacer patterned mask according to an embodiment of the present disclosure;

FIG. 5 is a schematic view illustrating a second polymer included in a second intermediate structure in a method for forming an anti-spacer patterned mask according to an embodiment of the present disclosure;

FIG. 6 is a chemical formula view illustrating a second polymer included in a second intermediate structure in a method for forming an anti-spacer patterned mask according to an embodiment of the present disclosure;

FIG. 7 is a flowchart illustrating a method for forming a patterned mask according to an embodiment of the present disclosure; and

FIG. 8 is a flowchart illustrating a method for forming a patterned mask according to an embodiment of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes, including relative thicknesses and/or widths of layers and structures shown in the drawings. One of ordinary skill in the art can appreciate many possible applications and variations for other embodiments based on the following illustrative and example embodiments provided in the present disclosure.

In the present disclosure, terms such as “first”, “second”, “third”, “fourth”, and the like, can be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments. Because semiconductor geometries and sizes can be so extremely small (e.g., on the order of 1 to 5 nm), the terms “film” and “layer” may be used interchangeably herein.

Ever continuous scaling can require improved patterning resolution. One approach is spacer technology to define a sub-resolution line feature via atomic layer deposition (ALD). One challenge, however, is that if the opposite tone feature is desired, using spacer techniques can involve a complex succession of operations, including over-coating with another material (an “overcoat”), using the spacer features as mandrels, chemical mechanical planarization (CMP), and reactive ion etch (RIE) to exhume the spacer material leaving a narrow trench, which can be costly. In such cases, spacer techniques can involve a complex and costly succession of steps, including over-coating with another material (an “overcoat”) using the spacer features as mandrels, chemical-mechanical planarization (CMP) to reveal the spacer features, and reactive ion etching (RIE) to remove the spacer material, leaving a narrow trench.

Anti-spacer technology is an alternate, self-aligned approach that can use the diffusion length of a reactive species across a boundary between an overcoat and an adjacent layer to define a critical dimension (CD), creating a narrow trench around the features of that adjacent layer after development of the overcoat or creating a narrow trench into the features of that adjacent layer after development of the diffusion changed regions. When generation of the reactive species is controlled spatially via exposure through a mask, finer features can be formed, such as a narrow slot contact. The CD itself can be tuned based on the physical and chemical properties of the reactive species (e.g., its molecular weight and affinity for interactions with the host material) and by modifying the bake temperature and bake time in a post exposure bake (PEB). As a result, anti-spacer techniques can enable patterning narrow slot-contact features at dimensions beyond the reach of advanced lithographic capabilities.

In some methods of forming an anti-spacer mask, an initial material property is being a so-called “protected” polymer that is not soluble in a typically-used developer, such as a quaternary ammonium hydroxide in an aqueous solution, or more specifically such as tetramethylammonium hydroxide (TMAH), for example. And then after a chemical transformation of the initial material to a given depth to form an anti-spacer region of a second material that is soluble in TMAH, such that the second material is a so-called “unprotected” polymer (with respect to TMAH). Next, when the wafer is developed using TMAH, the anti-spacer region can be removed to form openings, such as narrow line cuts, to form an anti-spacer mask. Accordingly, such recent methods of forming an anti-spacer mask typically start with a “protected” polymer (with respect to TMAH) that is converted to an “unprotected” polymer (with respect to TMAH) so that a development operation using TMAH as the developer will remove or etch away the “unprotected” polymer regions.

For example, the “protected” polymer that is converted to the “unprotected polymer” may be included as part of a first patterned resist layer, such as a patterned photoresist layer. Recent methods of forming an anti-spacer mask can deposit a second resist layer over a first patterned resist layer to fill in the space between features of the first patterned layer. The formulations used to coat the initial patterned layer must not dissolve the first resist. As an example, if the first resist is formulated in a nonpolar solvent system, the second resist can also be formed in a nonpolar solvent system (which may be different than the first nonpolar solvent system) so as not to affect the first resist. However, the second resist layer can include an overburden region overlying the “unprotected” polymer regions of the first patterned resist layer. This presents a challenge in the final development step to form the anti-spacer mask where a polar developer (such as aqueous TMAH) is used to remove the “unprotected” polymer because the second resist is insoluble in the polar developer. That is, the overburden region can prevent the polar developer from reaching the “unprotected” polymer regions of the first patterned resist layer and the method of forming the anti-spacer mask can fail.

In an embodiment of the present disclosure, a method of forming an anti-spacer mask use specific formulations of the second polymer in the second resist layer that do not affect the first patterned resist layer, but that can also have a non-zero dissolution rate (e.g., 0<X<20 Å/s more preferably 0.5-10 Å/s) in a polar developer used during an anti-spacer development step of a method of forming an anti-spacer mask. The second polymer can be deposited in a “protected” state that is soluble (e.g., highly soluble) in a nonpolar solvent system as part of a second resist layer over the first patterned resist layer. The “protected” second polymer can be deprotected using a solubility shifting agent (e.g., that does not affect the first resist) to form an “unprotected” second polymer that is soluble in the polar developer (i.e., has a non-zero dissolution rate).

In one embodiment of the present disclosure, the solubility shifting agent used to deprotect the second polymer is the same solubility shifting agent that is used to deprotect a first polymer forming the anti-spacer regions in the first patterned resist layer. For example, the solubility shifting agent may be diffused into the anti-spacer regions from an overcoat layer before the second resist layer is deposited. The solubility shifting agent may then diffuse from the anti-spacer region into at least the overburden region of the second resist layer. In some embodiments, the solubility shifting agent diffuses into the second resist layer without additional process steps (e.g., the process conditions of depositing the second resist layer and/or developing the anti-spacer are sufficient to diffuse the solubility shifting agent from the anti-spacer region into the second resist layer). In other embodiments, additional conditions are provided (whether simultaneously with or separately from other existing processing steps), such as applying heat in a baking process to promote diffusion. Alternatively or additionally, the second resist may be formulated with a second solubility shifting agent that is activated by supplying the required activation energy to release a catalyst portion of the second solubility shifting agent into some or all of the second resist layer that is used to deprotect the second polymer.

The second polymer may include one or more types of repeating polymer units. At least one of the repeating polymer units has a functional group that at least partially controls the solubility of the second polymer relative to nonpolar and polar solvents. The second polymer with the functional group exposed is initially insoluble with respect to nonpolar solvents (i.e., “unprotected” second polymer). A protecting group is attached to the functional group of the “unprotected” second polymer to shift the solubility of the second polymer so that it becomes soluble in nonpolar solvents (i.e., “protected” second polymer). Treatment of the “protected” second polymer with the solubility shifting agent (whether from the anti-spacer regions, included as part of the second resist, or a combination thereof) removes the protecting group (deprotects the second polymer) exposing the functional group and switching the solubility back to the initial state of being insoluble in nonpolar solvent (i.e., “deprotected” second polymer).

In a method of forming an anti-spacer mask according to an embodiment of the present disclosure, an advantage of deprotecting the second polymer to remove the protecting group and expose the functional group is that the deprotected second polymer also has a non-zero dissolution rate in polar solvents. Specifically, the deprotected second polymer is soluble in a polar developer used to remove or etch away an anti-spacer region, such as a TMAH developer. This can allow an overburden region (e.g., a “thin” overburden layer, such as thinner than the anti-spacer region, for example) of a second resist layer including the second polymer to be dissolved without removing remaining portions of the second resist layer enabling the anti-spacer region to be removed (i.e., developed).

In some embodiments of the present disclosure, a method for forming a patterned mask can include providing a first intermediate structure on a substrate, where the first intermediate structure includes a first material including a first polymer, where the first intermediate structure further includes a first converted region of a second material to a first depth into the first intermediate structure, and where the second material has been chemically transformed from the first material by at least a catalyst portion of a first solubility shifting agent diffused into the first converted region. The first material is soluble in a first solvent system containing a first nonpolar solvent, but is insoluble in a developer containing a polar solvent. However, the second material is soluble in the developer containing the polar solvent.

The method can further include providing a second intermediate structure on the substrate, where the second intermediate structure includes a third material including a second polymer with a functional group protected by a protecting group, and where the second intermediate structure includes an overburden region overlying the first converted region of the first intermediate structure. The third material is soluble in a second solvent system containing a second nonpolar solvent, but is insoluble in the developer containing the polar solvent.

The method can further include providing at least a catalyst portion of a second solubility shifting agent to the overburden region of the second intermediate structure and chemically transforming the overburden region of the second intermediate structure to a second converted region of a fourth material using the catalyst portion of the second solubility shifting agent as a chemical reaction catalyst, such that the fourth material is soluble in the developer containing the polar solvent. In one embodiment, substantially the entire second intermediate structure including the overburden region is transformed to the second converted region. In this implementation, the solubility of the fourth material in the developer may be lower than the solubility of the second material (e.g., an anti-spacer region). In another embodiment, substantially only the overburden region of the second intermediate structure is transformed to the second converted region. In this implementation, the solubility of the fourth material in the developer may be lower, similar, or higher than the solubility of the second material in the developer.

In various embodiments, the second polymer can include para-hydroxystyrene, where a hydroxyl group of the para-hydroxystyrene is protected by a vinyl ether protecting group. In some embodiments, the second polymer includes other polymers, such as styrene and/or an acrylate (e.g., tert-butyl acrylate). In some embodiments, the polar developer is an aqueous base developer, and is an aqueous TMAH developer in one embodiment. In some embodiments, the first intermediate structure can be a patterned photoresist layer (e.g., exposed using EUV radiation and developed using an EUV developer). In some embodiments, the second intermediate structure can be a second resist layer deposited over the patterned photoresist layer.

The first solubility shifting agent can be provided as the second solubility shifting agent (e.g., diffused from the first converted region of the first intermediate structure into the overburden region of the second resist layer) in some embodiments. Additionally or alternatively, the second solubility shifting agent may be included in the second intermediate structure (e.g., a catalyst portion of the second solubility shifting agent can be generated in the overburden region of the second intermediate structure by activating the second solubility shifting agent).

In some embodiments of the present disclosure, the method can further include depositing an overcoat layer over the first intermediate structure (e.g., a patterned photoresist layer) and the substrate, where the overcoat layer includes the first solubility shifting agent. The method can further include diffusing at least a catalyst portion of the first solubility shifting agent from the overcoat layer into the first region of the first intermediate structure and chemically transforming the first region of the first intermediate structure to a first converted region (e.g., anti-spacer regions) of a second material to a first depth into the first intermediate structure. The method can further include removing the overcoat layer leaving behind the first intermediate structure including the first converted region.

After the second converted regions of the fourth material are converted using the second solubility shifting agent, the method can further include removing the anti-spacer regions using the polar solvent of the developer to form an anti-spacer pattern comprising remaining portions of the first intermediate structure (e.g., a patterned photoresist layer) and the second intermediate structure (e.g., an additional resist layer including the second polymer). The anti-spacer pattern has openings (e.g., mask openings) to the substrate corresponding to the anti-spacer regions, where at least part of the openings has a critical dimension corresponding to the first depth. The method can further include etching the substrate through the mask openings to form openings in the substrate having the substantially the same critical dimension.

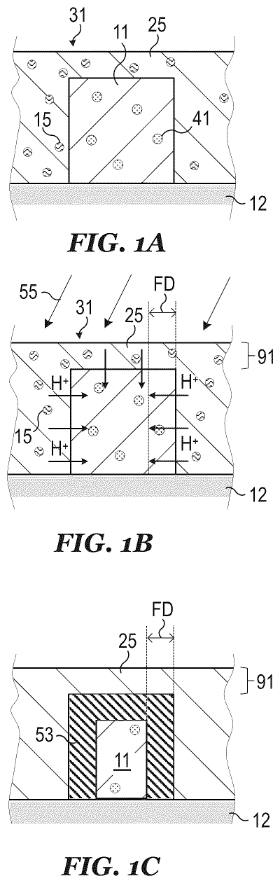

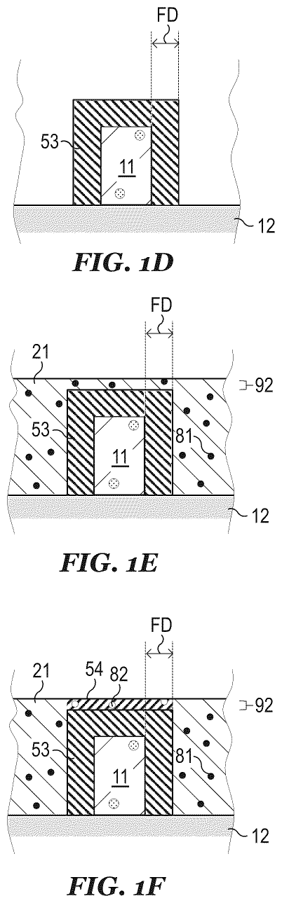

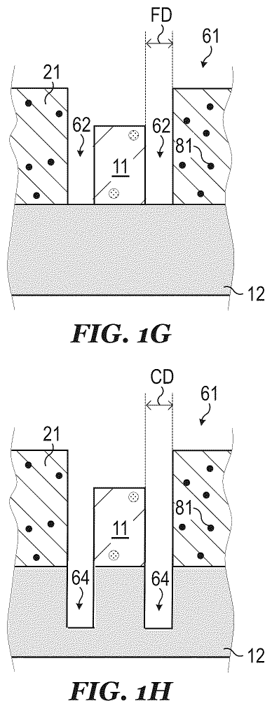

Some example embodiments of the present disclosure are described in detail with reference to FIGS. 1A to 8.

FIGS. 1A to 1F are cross-section views illustrating intermediate structures in a method for forming a patterned mask according to an embodiment of the present disclosure.

Referring to FIG. 1A, a first intermediate structure 11 can be provided on a substrate 12. The first intermediate structure 11 can include a first material, and the first material can include a first polymer 41. An overcoat layer 25 can be provided on the substrate 12. The overcoat layer 25 can include a first SSA 15 (a solubility shifting agent) therein. The overcoat layer 25 interfaces with the first intermediate structure 11 at least at a first region 31 (at a perimeter region of the first intermediate structure 11). The overcoat layer 25 has an overcoat overburden 91 that overlies the first intermediate structure 11 so that top surfaces of the first intermediate structure 11 are in adjacent to the overcoat layer 25.

The first material of the first intermediate structure 11 can be soluble in a solvent system containing a nonpolar solvent (e.g., a first solvent system) developer containing a polar solvent, but insoluble in a developer containing a polar solvent, such as an aqueous base developer (e.g., a quaternary ammonium hydroxide in an aqueous solution, one specific example of which is a TMAH developer including TMAH in aqueous solution).

In some embodiments, the first SSA 15 can be formed in situ during the deposition of the overcoat layer 25. In such case, the first SSA 15 can be evenly distributed throughout the overcoat layer 25, for example, but not necessarily. In some embodiments, the first overcoat layer 25 can be deposited without the SSA and the first SSA 15 can be put into the overcoat layer 25 thereafter. For example, in some embodiments, the first SSA 15 can be implanted or diffused into the overcoat layer 25.

The first region 31 of the first intermediate structure 11 including the first material can be adjacent and in direct physical contact with the overcoat layer 25 containing the first SSA 15. In some embodiments, there can be one or more intervening layers (not shown in the drawings) between the first intermediate structure 11 and the overcoat layer 25 at the first region 31 provided that certain materials can diffuse through such one or more intervening layers (diffusion discussed next).

In the present disclosure, for an embodiment, the term “substrate” (e.g., substrate 12) can be used generally and as a shorthand description for an underlying structure that can include any combination of layers, materials, structures, devices, and a wafer of any suitable structure. For example, the substrate 12 of an embodiment can include one or more bottom anti-reflective coating (BARC) layers, one or more developable BARC (dBARC) layers, one or more etch stop layers, one or more hard mask layers, one or more dielectric layers, one or more intermetal dielectric layers, one or more conductive lines/layers/interconnects, one or more transistor structures, one or more capacitor structures, one or more resistor structures, one or more inductor structures, one or more memory cells, or any combination thereof.

Referring to FIGS. 1B and 1C, at least a catalyst portion (e.g., an acid) of the first SSA 15 from the overcoat layer 25 can be diffused into the first region 31 (e.g., outer regions) of the first intermediate structure 11 and chemically transform the first region 31 of the first intermediate structure 11 to a converted region 53 (e.g., an anti-spacer region) of a second material (i.e., a second material chemically different from the first material) to a first depth FD into the first intermediate structure 11 using the catalyst portion of/from the first SSA 15 as a chemical reaction catalyst, such that the second material of the converted region 53 is soluble in the developer containing the polar solvent.

In the drawings for the present disclosure (e.g., FIGS. 1B, 2B, and 3B), for simplification of the drawings, “H⁺” can be used as shorthand notation to denote and represent a catalyst, which in some embodiments can be an acid, that is being diffused, such as an acid that donates a proton (e.g., H⁺) in a chemical reaction (e.g., as a catalyst). However, an acid being diffused in an embodiment of the present disclosure is not necessarily limited to one that provides a hydrogen ion. For example, “H⁺” may not necessarily accurately describe some acid species that can be used in an embodiment of the present disclosure, as can be apparent to one of ordinary skill in the art for which the present disclosure pertains. Thus, the use of “H⁺” is as a reference in the drawings for the catalyst is not intended to necessarily limit the chemical makeup or chemical action of the catalyst in an embodiment.

While describing the example embodiments of the present disclosure, the term “solubility shifting agent” or “SSA” can refer to a substance in a general sense that if not already a catalyst agent itself, it can generate and/or can transform (e.g., by heat and/or certain radiation of light) to a catalyst agent and/or constituent parts that includes a catalyst agent that can be used in a chemical reaction to shift or change a solubility property of a material.

In an embodiment, a first SSA 15 can include an agent-generating ingredient that, in response to a suitable agent-activation trigger (e.g., heat and/or radiation), generates a solubility-changing chemical (e.g., an acid). Example agent-generating ingredients can include a thermal-acid generator (TAG) that is configured to generate an acid in response to heat or a photo-acid generator (PAG) that is configured to generate an acid in response to actinic radiation.

In an embodiment, the catalyst of/from the first SSA 15 can cause the chemical reaction on the first polymer 41 to occur at a lower temperature, such as in a temperature range of 70° C. to 120° C., depending on the strength of an acid of/from the first SSA 15, and the choice of monomer/polymer, as compared to a temperature at which can be required to cause the first polymer 41 to convert to another material without the catalyst (without a certain acid present), such as in a temperature range of more than 150° C., or more than 180° C. in some cases, which can be outside the thermal budget for the materials used as photoresist, for example. Also, by limiting the diffusion depth (e.g., the first depth FD) of the catalyst (e.g., acid of/from the first SSA 15), a controlled region (e.g., the converted region 53) can be converted at a relatively lower temperature while the remainder of the first intermediate structure 11 not having the catalyst diffused therein remains unconverted, in accordance with an embodiment of the present disclosure.

For example, the chemical transforming of the first region 31 of the first intermediate structure 11 can include diffusing acid from the overcoat layer 25 into the first region 31 of the first intermediate structure 11 to increase solubility or change/shift solubility of the first region 31 for a given developer (e.g., the developer containing a polar solvent) such that the first region 31 of the first intermediate structure 11 becomes the converted region 53 of a second/different material.

For example, the overcoat layer 25 can include a free acid as a first SSA 15. During a baking operation, the free acid (represented as H⁺ in FIG. 1B) can diffuse into perimeter portions (first region 31) of the first intermediate structure 11 (i.e., regions adjacent and/or in physical contact with the overcoat layer 25 including the first SSA 15) and can cause the perimeter portions of the first intermediate structure 11 to become soluble in a given developer, where the original material (untransformed remaining portions) of the first intermediate structure 11 is not soluble or is orders of magnitude less soluble to the given developer.

As another example, the overcoat layer 25 can include a TAG as an agent-generating ingredient for the first SSA 15. Baking the substrate 12 (e.g., a wafer) can cause the TAG to generate a solubility-changing agent (e.g., acid, represented as H⁺ in FIG. 1B), which can be referred to as activating the acid, and the baking can also cause the generated solubility-changing agent to diffuse into perimeter portions (first region 31) of the first intermediate structure 11 and can cause the first region 31 of the first intermediate structure 11 to become soluble in a given developer, where the original material (untransformed remaining portions) of the first intermediate structure 11 is not soluble or is orders of magnitude less soluble to the given developer.

As another example, the overcoat layer 25 can include a PAG as an agent-generating ingredient for the first SSA 15. The overcoat layer 25 can be exposed to a radiation (e.g., actinic radiation) that can be performed prior to baking the wafer. Such exposure to radiation can cause the PAG to generate a solubility-changing agent (e.g., acid, represented as H⁺ in FIG. 1B), which can be referred to as activating the acid. Then, baking of the substrate 12 (e.g., a wafer) can cause the generated solubility-changing agent to diffuse into perimeter portions (first region 31) of the first intermediate structure 11 and can cause the first region 31 of the first intermediate structure 11 to become soluble in a given developer, where the original material (untransformed remaining portions) of the first intermediate structure 11 is not soluble or is orders of magnitude less soluble to the given developer.

In an embodiment, a baking process for forming the converted region 53 of the second material can be a thermal process that is performed by heating the substrate 12 in a process chamber to a temperature between 50° C. and 250° C., for example, or between 6° C. and 140° C. in certain embodiments, in vacuum or under a gas flow. In a particular example, the substrate 12 can be baked for a duration in a range from 1 to 3 minutes. The bake conditions can be selected to promote the diffusion of the solubility-changing agent (and possibly generation of the solubility-changing agent from an agent generating ingredient of the first SSA 15 in the overcoat layer 25) and associated change in solubility of the perimeter regions (first region 31) of the first intermediate structure 11 to a target first depth FD (see, e.g., FIGS. 1B and 1C).

The first depth FD can be tuned by parameters of the baking process (such as, for example, a bake temperature and a bake duration) and material parameters (such as, for example, a polymer composition of the first intermediate structure 11, and an acid composition and an acid concentration from the first SSA 15 in the overcoat layer 25). Some example materials that can be used for the first SSA 15 or generated from the first SSA 15 as a catalyst for the chemical reaction to shift/change the solubility of the first region 31 to the converted region 53 of the second material in an embodiment will be described later in the present disclosure.

In FIG. 1B, energy from heat and/or radiation used in the process of chemically transforming the first region 31 to the converted region 53 of the second material is illustrated generally by downward pointing arrows 55. However, as can be understood by one of ordinary skill in the art pertaining to such process, the direction(s) and vector(s) of the heat and/or radiation can be from any suitable direction(s)/vector(s) and from any suitable source of provided in a given tool. Hence, the downward pointing arrows 55 of FIG. 1B can be merely illustrative. Further, as already discussed, in some cases (e.g., when the first SSA 15 is a free acid), no additional energy may be necessary to diffuse at least the catalyst portion of the first SSA 15 into the first intermediate structure 11.

In the present disclosure, the terms “soluble” and “insoluble” are used in a relative sense, not in an absolute sense. That is, the term “insoluble” as used herein refers to one subject material being dissolved or removed much faster and much more effectively compared to another adjacent non-subject material, such as an order of magnitude or more faster and more effectively, and not to necessarily be that the other adjacent non-subject material experiences no dissolving or removal, but rather that the subject material is removed so much faster and more effectively that the subject material can be dissolved and removed sufficiently or to its full extent while only a small amount or even only a negligible amount of the other adjacent non-subject material is dissolved and removed, such that most of or almost all of the other adjacent non-subject material at the stopping point of the dissolving and removing of the subject material, as can be apparent to one of ordinary skill in the art pertaining to the present disclosure.

Referring now to FIG. 1D, a cross-section view of the substrate 12 illustrates the converted region 53 of the first intermediate structure 11 on the substrate 12 after the overcoat layer 25 has been removed. For example, the overcoat layer 25 may be removed through a solvent rinse (e.g., a nonpolar solvent rinse) since the converted region 53 is now insoluble in nonpolar solvent systems.

Turning to FIG. 1E, a cross-section view of the substrate 12 illustrates a second intermediate structure 21 that has been formed (e.g., deposited) over the first intermediate structure 11 including the converted region 53. The second intermediate structure 21 has a material overburden 92 overlying the converted region 53 of the first intermediate structure 11. The second intermediate structure 21 includes a third material that includes a second polymer 81 with a functional group protected by a protecting group. The third material is soluble in a solvent system containing a nonpolar solvent (which may include similar or different nonpolar solvents as the solvent system discussed in reference to the first intermediate structure 11), but the third material is insoluble in the developer containing the polar solvent. That is, without further modification, the material overburden 92 can prevent the converted region 53 from being removed by the developer containing the polar solvent.

Now referring to FIG. 1F, a cross section view of the substrate 12 illustrates the second intermediate structure 21 after a second converted region 54 has been formed in the material overburden 92 of the second intermediate structure 21. Specifically, at least a catalyst portion of a second solubility shifting agent is provided (e.g., diffused into and/or activated within) material overburden 92 of the second intermediate structure 21 and chemically transforms at least the region of the material overburden 92 adjacent to the converted region 53 to second converted region 54 of a fourth material using the catalyst portion of the second solubility shifting agent as a chemical reaction catalyst, such that the fourth material is soluble in the developer containing the polar solvent. That is, the further material includes a deprotected second polymer 82 that has non-zero solubility in the developer containing the polar solvent. An advantage of these and other embodiments of the present disclosure is that the fourth material dissolves in the developer containing the polar solvent allowing the converted region 53 to be removed.

FIG. 1G is a cross-section view illustrating an anti-spacer patterned mask 61 formed using the method portrayed in FIGS. 1A to 1F, according to an embodiment of the present disclosure. To form the anti-spacer patterned mask 61 shown in FIG. 1G, the converted region 53 of the second material can be removed using the developer containing the polar solvent to form mask openings 62 exposing the substrate 12 that are bounded by and defined by remaining portions (i.e., portions unconverted by the catalyst of/from the first SSA 15) of first intermediate structure 11 and of the second intermediate structure 21. Because the mask openings 62 can be formed by the removal of the converted region 53 of the second material, and because the converted region 53 can have dimensions defined by or corresponding to the first depth FD for which the catalyst of/from the first SSA 15 diffused into the first region 31 of the first intermediate structure 11, at least part of the mask openings 62 can have a critical dimension CD corresponding to the first depth FD. As shown in FIG. 1H, the mask openings 62 of the anti-spacer patterned mask 61 may then be used to etch substrate openings 64 into one or more underlying layers of the substrate 12.

The critical dimension CD is not necessarily equal to the first depth FD in some embodiments, but can be derived from and dependent upon the first depth FD for which most of or all of the catalyst of/from the first SSA 15 diffused into the first intermediate structure 11. Thus, a critical dimension CD of the mask openings 62 can be adjusted, tuned, and specified based on parameters (e.g., temperature, bake time, radiation energy, exposure time, etc.) for the process of diffusing the catalyst of/from the first SSA 15 and/or the process of causing the chemical reaction to form the second material of the converted region 53, as well as other factors, such as the choice of the substance for the catalyst of/from the first SSA 15, the first material of the first intermediate structure 11 (e.g., choice of photoresist material(s) and/or other additives), the choice of the first polymer 41 of the first intermediate structure 11, other additives/substances present also in the first intermediate structure 11, or any suitable combination thereof.

Although only two mask openings 62 are shown in FIG. 1G for purposes of simplified illustration, it can be apparent to one of ordinary skill in the art that in an embodiment there can numerous openings for the anti-spacer patterned mask 61 of various shapes and sizes across a given die and across a wafer while implementing an embodiment of the present disclosure.

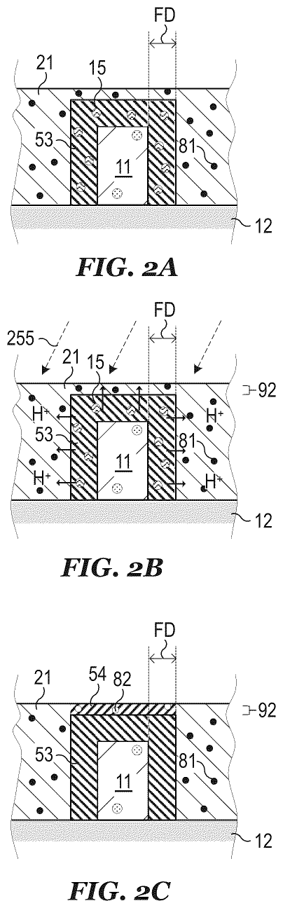

FIGS. 2A to 2C are cross-section views illustrating intermediate structures in a method for forming an anti-spacer patterned mask according to an embodiment of the present disclosure. Referring to FIG. 2A, a substrate 12 includes a first intermediate structure 11 and a second intermediate structure 21 and is similar to the substrate 12 of FIG. 1E, except that in the specific example of FIG. 2A, the first SSA 15 (or at least a catalyst of the first SSA 15) has diffused into the converted region 53. Then, as shown in FIGS. 2B and 2C, at least the catalyst portion of the first SSA 15 is diffused from the second material of the converted region 53 into the material overburden 92 of the second intermediate structure chemically transforming the material overburden 92 of the second intermediate structure 21 to the second converted region 54 of the fourth material including the deprotected second polymer 82.

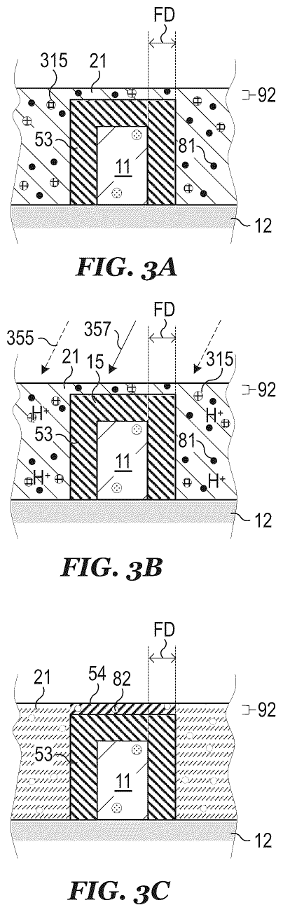

FIGS. 3A to 3C are cross-section views illustrating intermediate structures in a method for forming an anti-spacer patterned mask according to an embodiment of the present disclosure. Referring to FIGS. 3A and 3B, a substrate 12 includes a first intermediate structure 11 and a second intermediate structure 21 and is similar to the substrate 12 of FIG. 1E, except that in the specific example of FIG. 3A, a second SSA 315 is included in the second intermediate structure 21 along with the second polymer 81. The second SSA 315 may be selected so that it requires additional activation energy to generate a catalyst portion of the second SSA 315 in the second intermediate structure 21.

Specifically, additional energy is provided to at least the material overburden 92 of the second intermediate structure 21 illustrated generally as downward arrow 357 in FIG. 2B (with dashed downward arrows 355 being optionally included to provide additional energy to other portions of the second intermediate structure 21). The additional energy may be from heat and/or radiation as described in other places throughout the present disclosure. The additional energy activates the second SSA 315 to generate (e.g., release) at least the catalyst portion of the second SSA 315 within at least the material overburden 92 of the second intermediate structure 21. Now referring to FIG. 3C, the material overburden 92 of the second intermediate structure 21 is chemically transformed to the second converted region 54 of the fourth material including the deprotected second polymer 82.

In some embodiments, such as when the additional energy is provided to all portions of the second intermediate structure 21 (e.g. dashed downward arrows 355), some or all of remaining portions of the second intermediate structure 21 may also be chemically transformed as indicated by the dashed shaded regions of the second intermediate structure 21 adjacent to the first intermediate structure 11. The dissolution rate of the fourth material of the second converted region 54 and the other converted regions in the developer containing the polar solvent may be selected to be less than the dissolution rate of the second material of the converted region 53 in the developer so as to allow the fourth material portion of the second intermediate structure 21 adjacent to the first intermediate structure 11 to remain on the substrate 12 during the removal (development) of the converted region 53 resulting in a substantially similar structure as that shown in FIG. 1G.

Many example materials for a first SSA 15, a second SSA 315, a first polymer 41, a second material of a converted region 53, a second polymer 81, a fourth material of a second converted region 54, and a solvent system containing a nonpolar solvent, relating to the example embodiments of FIGS. 1A to 3C, will be described below in the present disclosure.

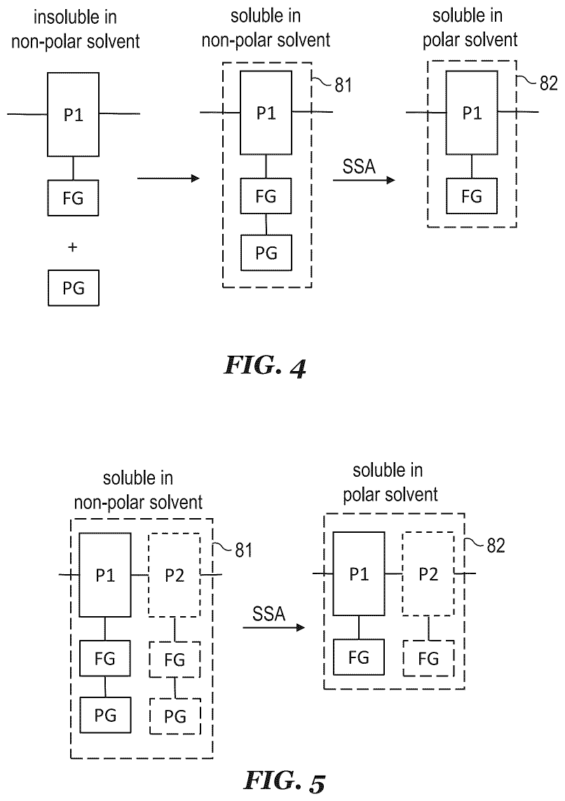

FIG. 4 is a schematic view illustrating a second polymer included in a second intermediate structure in a method for forming an anti-spacer patterned mask according to an embodiment of the present disclosure. Referring to FIG. 4, a second polymer 81 includes a repeated unit P1 that includes a functional group FG. As previously discussed, the functional group FG controls a degree of solubility of the second polymer 81 relative to nonpolar solvents and/or polar solvents. In an initial state, the second polymer 81 with an exposed functional group FG is insoluble in nonpolar solvent, but soluble in polar solvents (i.e., with some non-zero solubility in polar solvent).

Because the initial unprotected state of the second polymer 81 is insoluble in nonpolar solvent, the initial state is not suitable for use as the second polymer 81 in a second intermediate structure, such as a second resist layer used to form an anti-spacer mask when the first intermediate structure 11 is a photoresist layer that is patterned (i.e., developed) with certain types of developers. For example, when the first intermediate structure 11 is a photoresist layer patterned using an EUV resist, the first polymer of the first intermediate structure 11 is soluble in nonpolar solvent systems. In order for the third material including the deprotected second polymer 82 to not interfere with the patterned photoresist layer, it can also be selected to be soluble in a nonpolar solvent system. However, the unprotected initial state of the second polymer 81 is insoluble in nonpolar solvent.

Protecting the functional group FG with a protecting group PG shifts the solubility of the second polymer 81. Specifically, the protected second polymer 81 is soluble in nonpolar solvent. For this reason, before including the second polymer 81 in a nonpolar solvent system for deposition as part of the third material of a second intermediate structure 21 (such as a second resist layer), the functional group FG of the second polymer 81 is protected using the protecting group PG. An SSA (such as the first SSA 15 of the first intermediate structure 11 or a second SSA 315 included in the second intermediate structure 21) can then be used to cleave the protecting group PG from the functional group FG to form a deprotected second polymer 82 that is soluble in polar solvent. As previously discussed, the solubility of the deprotected second polymer 82 may be relatively weak solubility compared to the solubility of a converted region 53 (e.g., an anti-spacer region) of an adjacent first intermediate structure 11. However, the non-zero dissolution rate (e.g., 0<X<10 A/s) of the deprotected second polymer 82 in a polar solvent, such as a polar developer like an aqueous TMAH developer, is sufficient to allow a material overburden 92 of a second intermediate structure 21 to be removed so that an underlying converted region 53 can be removed with the polar solvent.

As an example, the first material of a first intermediate structure 11 may be a photoresist that includes a polymer (e.g., a first polymer 41), a photoacid generator, and a solvent. In one or more embodiments, the polymer may be any standard polymer typically used with photoresist material and may particularly be a polymer having acid-labile groups. Specifically, the first polymer 41 may be formed from a vinyl aromatic-based polymer, (which may be used for various photoresists, such as for KrF and EUV photoresists), and the resist may be developed as a positive tone development (PTD) resist. In this case a solvent system may be used that includes two or more types of nonpolar solvent. In various embodiments, the solvent system includes one or more nonpolar organic solvents. The term “nonpolar organic-based” may refer to having greater than 50 wt % of combined nonpolar organic solvents based on total solvents of the solubility—shifting agent composition, more typically greater than 70 wt %, greater than 85 wt % or 100 wt %, combined nonpolar organic solvents, based on total solvents of the composition of the first material. The nonpolar organic solvents are typically present in the solvent system in a combined amount of from 70 to 98 wt %, preferably 80 to 95 wt %, more preferably from 85 to 98 wt %, based on the solvent system.

So in other words, in order to not affect the first resist, the second resist must also be formulated in a nonpolar solvent. This presents a challenge for the final develop step when the solubility-shifted region (converted region 53) of the first intermediate structure 11 (e.g., of a patterned photoresist layer) is removed. A common developer for the final develop process is an aqueous base developer, one specific example of which is 0.26 N TMAH (other aqueous base developer as also discussed throughout this disclosure). This developer is very polar, and thus opposite of the nonpolar solvent used in the second resist formulation. This presents a major challenge, as the desirable material must have both excellent solubility in a nonpolar solvents but then a low but non-zero dissolution rate in the developer.

In various embodiments, the repeated unit P1 of the second polymer 81 is a standard polymer typically used in photoresist material and is a polymer that includes acid-labile groups in some embodiments. In some embodiments, the repeated unit P1 may be a monomer including para-hydroxystyrene, styrene, tert-butyl acrylate (PHS/S/TBA), and combinations thereof. In some embodiments, the repeated unit P1 is or includes other monomers, such as other vinyl aromatic monomers, acrylic acid, methacrylic acid, other acrylates or methacrylates such as 2-hydroxyethyl acrylate, 2-hydroxyethyl methacrylate, another acrylate or methacrylate functionalized with a carbohydrate, norbornene, or any combination thereof.

Functional groups, such as the hydroxyl group (—OH) of para-hydroxystyrene may be protected with a tert-butyloxycarbonyl protecting group or an acetal protecting group. Such protecting groups may alter the reactivity and solubility of the polymer included in the second resist. As will be appreciated by one having ordinary skill in the art, various protecting groups may be used for this reason, such as acid-labile groups that include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-decomposable groups”, “acid-cleavable groups,” “acid-cleavable protecting groups,” “acid-labile protecting groups,” “acid-leaving groups,” and “acid-sensitive groups.” One specific category of protecting groups that may be used are vinyl ether protecting groups. That vinyl ether protecting group may include various alkyl groups. In various embodiments, the protecting group is a vinyl ether protecting group including an isobutyl vinyl ether, methyl vinyl ether, ethylhexyl vinyl ether, 2-ethylheptyl vinyl ether, cyclohexyl vinyl ether, octadecyl vinyl ether, or combinations thereof.

FIG. 5 is a schematic view illustrating a second polymer included in a second intermediate structure in a method for forming an anti-spacer patterned mask according to an embodiment of the present disclosure. Referring to FIG. 5, in an embodiment, a second polymer 81 can include more than one type of repeated unit. For example, in addition to the repeated unit P1, the second polymer 81 may include a second repeated unit P2, and so on. Each additional type of repeated unit (P2, etc.) may or may not include a functional group FG that may or may not be the same as the functional group FG of the repeated unit P1. When included, the functional group FG of the additional repeated units may be protected using a protecting group PG. Deprotecting the included functional groups (FG) using an SSA chemically transforms the second polymer 81 into the deprotected second polymer 82 shifting the solubility as previously described.

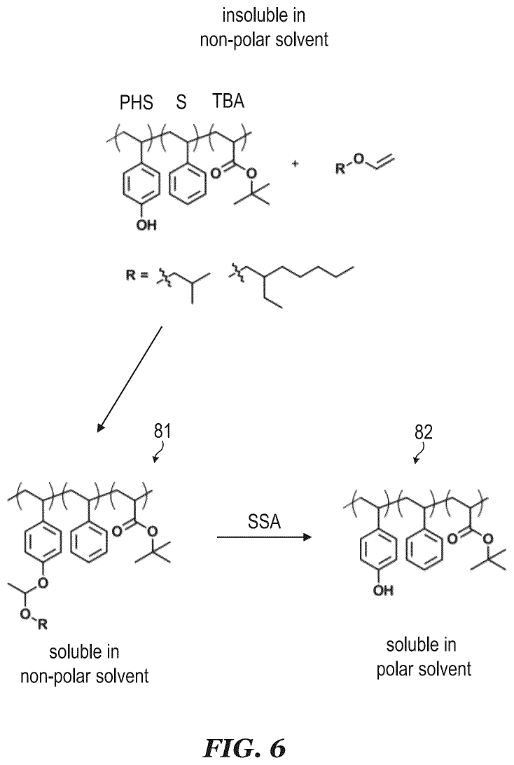

FIG. 6 is a chemical formula view illustrating a second polymer included in a second intermediate structure in a method for forming an anti-spacer patterned mask according to an embodiment of the present disclosure. Referring to FIG. 6, a specific example of a second polymer 81 that includes three repeated units, one of which is protected using a protecting group is illustrated. In particular, the second polymer 81 illustrated in FIG. 6 includes para-hydroxstyrene, styrene, and tert-butyl acrylate (PHS/S/TBA). The hydroxyl group of the PHS units is a functional group that is protected using a vinyl ether protecting group to form the second polymer 81. The second polymer 81 containing PHS/S/TBA may be prepared from a polymerization reaction including from about 50 to 80% para-hydroxystyrene, from about 10 to 30% styrene, and from about 10 to 30% tert-butyl acrylate.

In the unprotected state, the second polymer 81 is again insoluble in nonpolar solvent (rendering it incompatible for use with certain developers, such as EUV developers). Protecting the hydroxyl group with a vinyl ether protecting group shifts the solubility of the second polymer 81 so that it becomes soluble in nonpolar solvent and can be deposited over a patterned photoresist layer, for example. The introduction of an SSA removes the vinyl ether protecting group forming a deprotected second polymer 82 that is soluble in polar solvent be virtue of the hydroxyl group of the para-hydroxystyrene units again being exposed.

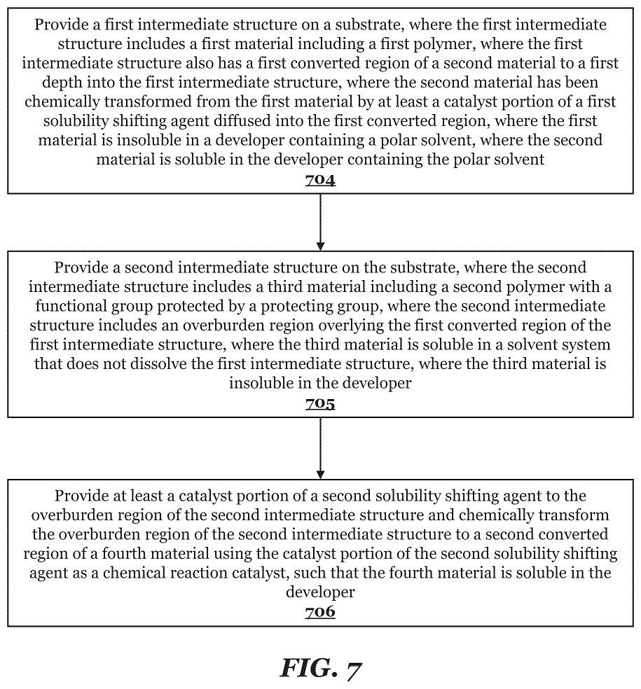

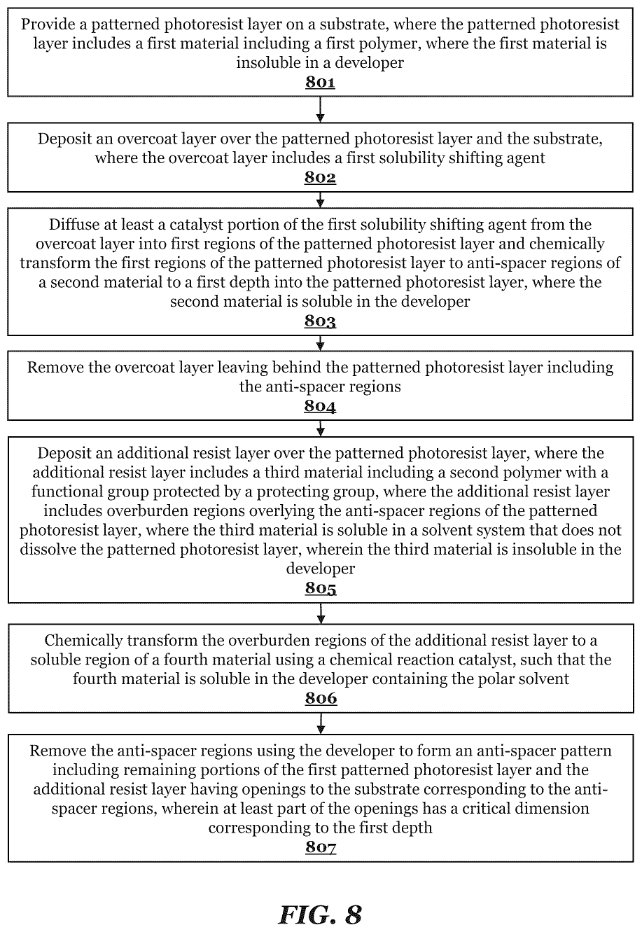

FIGS. 7 and 8 provide some example flowcharts illustrating some example methods that can be used for making the example embodiments described above and shown in FIGS. 1A to 6, as well as other embodiments.

FIG. 7 is a flowchart illustrating a method for forming a patterned mask according to an embodiment of the present disclosure. In a method for forming a patterned mask, the method can include providing a first intermediate structure on a substrate (box 704). The first intermediate structure includes a first material including a first polymer. The first intermediate structure also has a first converted region of a second material to a first depth into the first intermediate structure. The second material has been chemically transformed from the first material by at least a catalyst portion of a first solubility shifting agent diffused into the first converted region. The first material may be soluble in a solvent system containing a nonpolar solvent. The first material is insoluble in a developer containing a polar solvent. The second material is soluble in the developer containing the polar solvent.

In a method for forming a patterned mask, the method can include providing a second intermediate structure on the substrate (box 705). The second intermediate structure includes a third material including a second polymer with a functional group protected by a protecting group. The second intermediate structure includes an overburden region overlying the first converted region of the first intermediate structure. The third material is soluble in a solvent system that does not dissolve the first intermediate structure, such as aa solvent system containing a nonpolar solvent, but is insoluble in the developer containing the polar solvent.

In a method for forming a patterned mask, the method can include providing at least a catalyst portion of a second solubility shifting agent to the overburden region of the second intermediate structure and chemically transforming the overburden region of the second intermediate structure to a second converted region of a fourth material using the catalyst portion of the second solubility shifting agent as a chemical reaction catalyst, such that the fourth material is soluble in the developer containing the polar solvent (box 706).

In various embodiments, the second polymer can include para-hydroxystyrene, where a hydroxyl group of the para-hydroxystyrene is protected by a vinyl ether protecting group. In some embodiments, the second polymer includes other polymers, such as styrene and/or an acrylate (e.g., tert-butyl acrylate). In some embodiments, the polar developer is an aqueous base developer, and is an aqueous TMAH developer in one embodiment. In some embodiments, the first intermediate structure can be a patterned photoresist layer (e.g., exposed using EUV radiation and developed using an EUV developer that includes a polar solvent). In some embodiments, the second intermediate structure can be a second resist layer deposited over the patterned photoresist layer.

FIG. 8 is a flowchart illustrating a method for forming a patterned mask according to an embodiment of the present disclosure. In a method for forming a patterned mask, the method can include providing a patterned photoresist layer on a substrate, where the patterned photoresist layer includes a first material including a first polymer, where the first material is insoluble in a developer containing a polar solvent (box 801), depositing an overcoat layer over the patterned photoresist layer and the substrate, where the overcoat layer includes a first solubility shifting agent (box 802), diffusing at least a catalyst portion of the first solubility shifting agent from the overcoat layer into first regions of the patterned photoresist layer and chemically transforming the first regions of the patterned photoresist layer to anti-spacer regions of a second material to a first depth into the patterned photoresist layer, where the second material is soluble in the developer containing the polar solvent (box 803), and removing the overcoat layer leaving behind the patterned photoresist layer including the anti-spacer regions (box 804).

In a method for forming a patterned mask, the method can include depositing an additional resist layer over the patterned photoresist layer (box 805). The additional resist layer includes a third material including a second polymer with a functional group protected by a protecting group. The additional resist layer includes overburden regions overlying the anti-spacer regions of the patterned photoresist layer. The third material is soluble in a solvent system that does not dissolve the patterned photoresist layer, such as a solvent system containing a second nonpolar solvent, but is insoluble in the developer containing the polar solvent.

In a method for forming a patterned mask, the method can include chemically transforming the overburden regions of the additional resist layer to a soluble region of a fourth material using a chemical reaction catalyst, such that the fourth material is soluble in the developer containing the polar solvent (box 806). In an embodiment, the overburden regions of the additional resist layer are chemically transformed by diffusing at least a catalyst portion of the first solubility shifting agent as the chemical reaction catalyst from the anti-spacer regions of the first patterned photoresist layer into the overburden regions. In another embodiment that may be implemented as an alternative or in addition to the previous embodiment, the overburden regions of the additional resist layer are chemically transformed by generating a catalyst portion of a second solubility shifting agent in the overburden region of the second intermediate structure as the chemical reaction catalyst by activating the second solubility shifting agent.

In a method for forming a patterned mask, the method can include removing the anti-spacer regions using the polar solvent of the developer to form an anti-spacer pattern including remaining portions of the first patterned photoresist layer and the additional resist layer having openings to the substrate corresponding to the anti-spacer regions, wherein at least part of the openings has a critical dimension corresponding to the first depth (box 807). The patterned mask may be used as an etch mask to etch underlying layers of the substrate, for example.

For describing some example materials that can be implemented and used in an embodiment of the present disclosure, some example definitions will be provided next. These definitions are intended to supplement and illustrate, not preclude, definitions known to those of skill in the art, as can be apparent to one of ordinary skill in the art to which the present disclosure pertains.

The term “independently selected” as used herein can indicate that the R groups, such as, R1, R2, R3, R4, and R5 can be identical or different (e.g., R1, R2, R3, R4, and R5 may all be substituted alkyls or R1 and R2 may be a substituted alkyl and R3 may be an aryl, etc.). Use of the singular can include use of the plural, and vice versa (e.g., a hexane solvent can include hexanes). A named R group can generally have the structure that is recognized in the art as corresponding to R groups having that name.

The term “aliphatic” can refer to a non-aromatic saturated or unsaturated straight or branched hydrocarbon radical of from 1 to 40 carbon atoms or from 1 to 18 carbon atoms.

By “substituted” as in “substituted aliphatic moiety,” “substituted aryl,” “substituted alkyl,” and “substituted alkenyl,” as alluded to in some of the aforementioned definitions, can be indicate that in the hydrocarbyl, hydrocarbylene, alkyl, alkenyl, aryl or other moiety, at least one hydrogen atom bound to a carbon atom is replaced with one or more substituents that are groups such as hydroxyl, alkoxy, alkylthio, amino, halo, and silyl, to name a few. When the term “substituted” appears prior to a list of possible substituted groups, it can be intended that the term applies to every member of that group. For example, the phrase “substituted alkyl, alkenyl, and alkynyl” can be interpreted as “substituted alkyl, substituted alkenyl, and substituted alkynyl.” Similarly, “optionally substituted alkyl, alkenyl, and alkynyl” can be interpreted as “optionally substituted alkyl, optionally substituted alkenyl, and optionally substituted alkynyl.”

The term “substitution” can indicate each hydrogen atom (H) bonded to a carbon atom or heteroatom of a corresponding unsubstituted compound or functional group is replaced by a substituent (e.g., Rs). The term “polysubstitution” can indicate each of at least two, but not all, hydrogen atoms bonded to carbon atoms or heteroatoms of a corresponding unsubstituted compound or functional group is replaced by a substituent. The (C1-C18)alkylene and (C1-C8)alkylene substituents can be especially useful for forming substituted chemical groups that are bicyclic or tricyclic analogs of corresponding monocyclic or bicyclic unsubstituted chemical groups, for example.

The term “(C1-C40)hydrocarbyl” can refer to a hydrocarbon radical of from 1 to 40 carbon atoms and the term “(C1-C40)hydrocarbylene” can refer to a hydrocarbon diradical of from 1 to 40 carbon atoms, in which each hydrocarbon radical and diradical independently is aromatic (6 carbon atoms or more) or non-aromatic, saturated or unsaturated, straight chain or branched chain, cyclic (including mono- and poly-cyclic, fused and non-fused polycyclic, including bicyclic; 3 carbon atoms or more) or acyclic, or a combination of two or more thereof, and each hydrocarbon radical and diradical independently can be the same as or different from another hydrocarbon radical and diradical, respectively, and independently can be unsubstituted or substituted by one or more Rs.

In the present disclosure, a (C1-C40)hydrocarbyl independently can be an unsubstituted or substituted (C1-C40)alkyl, (C3-C40)cycloalkyl, (C3-C20)cycloalkyl-(C1-C20)alkylene, (C6-C40)aryl, or (C6-C20)aryl-(C1-C20)alkylene. In some embodiments, each of the aforementioned (C1-C40)hydrocarbyl groups independently has a maximum of 20 carbon atoms (i.e., (C1-C20)hydrocarbyl) and in other embodiments, a maximum of 12 carbon atoms, for example.

The terms “(C1-C40)alkyl” and “(C1-C18)alkyl” can refer to a saturated straight or branched hydrocarbon radical of from 1 to 40 carbon atoms or from 1 to 18 carbon atoms, respectively, that is unsubstituted or substituted by one or more Rs. Examples of unsubstituted (C1-C40)alkyl are: unsubstituted (C1-C20)alkyl; unsubstituted (C1-C10)alkyl; unsubstituted (C1-C5)alkyl; methyl; ethyl; 1-propyl; 2-propyl; 1-butyl; 2-butyl; 2-methylpropyl; 1,1-dimethylethyl; 1-pentyl; 1-hexyl; 1-heptyl; 1-nonyl; and 1-decyl. Examples of substituted (C1-C40)alkyl are substituted (C1-C20) alkyl, substituted (C1-C10)alkyl, trifluoromethyl, and (C45)alkyl. The (C45)alkyl is, for example, a (C27-C40)alkyl substituted by one Rs, which is a (C1-C5)alkyl, respectively. In some embodiments, each (C1-C5)alkyl independently is methyl, trifluoromethyl, ethyl, 1-propyl, 1-methylethyl, or 1,1-dimethylethyl, for example.

The term “(C6-C40)aryl” can refer to an unsubstituted or substituted (by one or more Rs) mono-, bi-, or tricyclic aromatic hydrocarbon radical of from 6 to 40 carbon atoms, of which at least from 6 to 14 of the carbon atoms are aromatic ring carbon atoms, and the mono-, bi-, or tricyclic radical comprises 1, 2 or 3 rings, respectively; wherein the 1 ring is aromatic and the 2 or 3 rings independently are fused or non-fused and at least one of the 2 or 3 rings is aromatic. Examples of unsubstituted (C6-C40)aryl are: unsubstituted (C6-C20)aryl unsubstituted (C6-C18)aryl; 2-(C1-C5)alkyl-phenyl; 2,4-bis(C1-C5)alkyl-phenyl; phenyl; fluorenyl; tetrahydrofluorenyl; indacenyl; hexahydroindacenyl; indenyl; dihydroindenyl; naphthyl; tetrahydronaphthyl; and phenanthrene. Examples of substituted (C6-C40)aryl are: substituted (C1-C20)aryl; substituted (C6-C18)aryl; 2,4-bis[(C20)alkyl]-phenyl; polyfluorophenyl; pentafluorophenyl; and fluoren-9-one-1-yl.

The term “(C3-C40)cycloalkyl” can refer to a saturated cyclic hydrocarbon radical of from 3 to 40 carbon atoms that is unsubstituted or substituted by one or more Rs. Other cycloalkyl groups (e.g., (C3-C12)alkyl) can be defined in an analogous manner. Examples of unsubstituted (C3-C40)cycloalkyl are: unsubstituted (C3-C20)cycloalkyl, unsubstituted (C3-C10)cycloalkyl, cyclopropyl, cyclobutyl, cyclopentyl, cyclohexyl, cycloheptyl, cyclooctyl, cyclononyl, and cyclodecyl. Examples of substituted (C3-C40)cycloalkyl are: substituted (C3-C20)cycloalkyl, substituted (C3-C10)cycloalkyl, cyclopentanon-2-yl, and 1-fluorocyclohexyl.

Examples of (C1-C40)hydrocarbylene are: unsubstituted or substituted (C6-C40)arylene, (C3-C40)cycloalkylene, and (C1-C40)alkylene (e.g., (C1-C20)alkylene). In some embodiments, the diradicals are a same carbon atom (e.g., —CH2—) or on adjacent carbon atoms (i.e., 1,2-diradicals), or are spaced apart by one, two, or more intervening carbon atoms (e.g., respective 1,3-diradicals, 1,4-diradicals, etc.), for example. Some embodiments incorporate a 1,2-, 1,3-, 1,4-, or an alpha, omega-diradical, and others a 1,2-diradical, for example. The alpha, omega-diradical can be a diradical that has maximum carbon backbone spacing between the radical carbons. Some embodiments can incorporate a 1,2-diradical, 1,3-diradical, or 1,4-diradical version of (C6-C18)arylene, (C3-C20)cycloalkylene, or (C2-C20)alkylene.

The term “(C1-C40)alkylene” can refer to a saturated straight chain or branched chain diradicals (i.e., the radicals are not on ring atoms) of from 1 to 40 carbon atoms that is unsubstituted or substituted by one or more Rs. Examples of unsubstituted (C1-C40)alkylene are: unsubstituted (C1-C20)alkylene, including unsubstituted 1,2-(C2-C10)alkylene; including unsubstituted 1,3-(C3-C10)alkylene; 1,4-(C4-C10)alkylene; —C—, —CH2CH2—, —(CH2)—, —CH2CHCH3, —(CH2)4—, —(CH2)5—, —(CH2)6—, —(CH2)7—, —(CH2)8—, and —(CH2)4C(H)(CH3)—. Examples of substituted (C1-C40)alkylene are: substituted (C1-C20)alkylene, —CF2—, —C(O)—, and —(CH2)14C(CH3)2(CH2)5—(i.e., a 6,6-dimethyl substituted normal-1,20-eicosylene). As mentioned previously two Rs may be taken together to form a (C1-C18)alkylene, examples of substituted (C1-C40)alkylene also include 1,2-bis(methylene)cyclopentane, 1,2-bis(methylene)cyclohexane, 2,3-bis(methylene)-7,7-dimethyl-bicyclo[2.2.1]heptane, and 7,3-bis(methylene)bicyclo[2.2.2]octane.

The term “(C3-C40)cycloalkylene” can refer to a cyclic diradical (i.e., the radicals are on ring atoms) of from 3 to 40 carbon atoms that is unsubstituted or substituted by one or more Rs.

The term “heteroatom,” “heterohydrocarbon” can refer to a molecule or molecular framework in which one or more carbon atoms are replaced with an atom other than carbon or hydrogen. The term “(C1-C40)heterohydrocarbyl” can refer to a heterohydrocarbon radical of from 1 to 40 carbon atoms and the term “(C1-C40)heterohydrocarbylene” can refer to a heterohydrocarbon diradical of from 1 to 40 carbon atoms, and each heterohydrocarbon independently has one or more heteroatoms, for example O, S, S(O), S(O)2, Si(RC)2, P(RP), and N(RN). Independently each RC is unsubstituted (C1-C18)hydrocarbyl, each RP is unsubstituted (C1-C19)hydrocarbyl, and each RN is unsubstituted (C1-C18)hydrocarbyl or absent. When RN is absent then N comprises —N=. The heterohydrocarbon radical, and each of the heterohydrocarbon diradicals, independently is on a carbon atom or heteroatom thereof, and in most embodiments, it is on a carbon atom when bonded to a heteroatom formula (I) or to a heteroatom of another heterohydrocarbyl or heterohydrocarbylene. Each (C1-C40)heterohydrocarbyl and (C1-C40)heterohydrocarbylene independently is unsubstituted or substituted (by one or more Rs), aromatic or non-aromatic, saturated or unsaturated, straight chain or branched chain, cyclic (including mono- and poly-cyclic, fused and non-fused polycyclic) or acyclic, or a combination of two or more thereof; and each is respectively the same as or different from another.

In some embodiments, the (C1-C40)heterohydrocarbyl independently can be unsubstituted or substituted (C1-C40)heteroalkyl, (C1-C40)hydrocarbyl-O—, (C1-C40)hydrocarbyl-S—, (C1-C40)hydrocarbyl-S(O)—, (C1-C40)hydrocarbyl-S(O)2—, (C1-C40)hydrocarbyl-Si(Rc)2—, (C1-C40)hydrocarbyl-N(RN)—, (C1-C40)hydrocarbyl-P(RP)—, (C2-C40)heterocycloalkyl, (C2-C19)heterocycloalkyl-(C1-C20)alkylene, (C3-C20cycloalkyl-(C1-C19)heteroalkylene, (C2-C19)heterocycloalkyl-(C1-C20)heteroalkylene, (C1-C40)heteroaryl, (C1-C19)heteroaryl-(C1-C20)alkylene, (C6-C20)aryl-(C1-C19)heteroalkylene, or (C1-C19)heteroaryl-(C1-C20)heteroalkylene, for example.

The term “(C4-C40)heteroaryl” can refer to an unsubstituted or substituted (by one or more Rs) mono-, bi-, or tricyclic heteroaromatic hydrocarbon radical of from 1 to 40 total carbon atoms and from 1 to 4 heteroatoms, and the mono-, bi-, or tricyclic radical can include 1, 2, or 3 rings, respectively, wherein the 2 or 3 rings independently can be fused or non-fused and at least one of the 2 or 3 rings can be heteroaromatic. Other heteroaryl groups (e.g., (C4-C12)heteroaryl) can be defined in an analogous manner. The monocyclic heteroaromatic hydrocarbon radical can be a 5-membered or 6-membered ring. The 5-membered ring can have from 2 to 4 carbon atoms and from 3 to 1 heteroatoms, respectively, each heteroatom being 0, S, N, or P. Examples of 5-membered ring heteroaromatic hydrocarbon radical are: pyrrol-1-yl; pyrrol-2-yl; furan-3-yl; thiophen-2-yl; pyrazol-1-yl; isoxazol-2-yl; isothiazol-5-yl; imidazol-2-yl; oxazol-4-yl; thiazol-2-yl; 1,2,4-triazol-1-yl; 1,3,4-oxadiazol-2-yl; 1,3,4-thiadiazol-2-yl; tetrazol-1-yl; tetrazol-2-yl; and tetrazol-5-yl. The 6-membered ring can have 4 or 5 carbon atoms and 2 or 1 heteroatoms, the heteroatoms being N or P. Examples of 6-membered ring heteroaromatic hydrocarbon radical are: pyridine-2-yl; pyrimidin-2-yl; and pyrazin-2-yl. The bicyclic heteroaromatic hydrocarbon radical can be a fused 5,6- or 6,6-ring system. Examples of the fused 5,6-ring system bicyclic heteroaromatic hydrocarbon radical are: indol-1-yl; and benzimidazole-1-yl. Examples of the fused 6,6-ring system bicyclic heteroaromatic hydrocarbon radical are: quinolin-2-yl; and isoquinolin-1-yl. The tricyclic heteroaromatic hydrocarbon radical can be a fused 5,6,5-; 5,6,6-; 6,5,6-; or 6,6,6-ring system. An example of the fused 5,6,5-ring system is 1,7-dihydropyrrolo[3,2-f]indol-1-yl. An example of the fused 5,6,6-ring system is 1H-benzo[f]indol-1-yl. An example of the fused 6,5,6-ring system is 9H-carbazol-9-yl. An example of the fused 6,5,6-ring system is 9H-carbazol-9-yl. An example of the fused 6,6,6-ring system is acrydin-9-yl.

The aforementioned heteroalkyl and heteroalkylene groups can be saturated straight or branched chain radicals or diradicals, respectively, containing (C1-C40) carbon atoms, or fewer carbon atoms and one or more of the heteroatoms Si(Rc)2, P(RP), N(RN), N, O, S, S(O), and S(O)2 as defined above, wherein each of the heteroalkyl and heteroalkylene groups independently can be unsubstituted or substituted by one or more Rs.

Examples of unsubstituted (C2-C40)heterocycloalkyl are: unsubstituted (C2-C20)heterocycloalkyl, unsubstituted (C2-C10)heterocycloalkyl, aziridin-1-yl, oxetan-2-yl, tetrahydrofuran-3-yl, pyrrolidin-1-yl, tetrahydrothiophen-S,S-dioxide-2-yl, morpholin-4-yl, 1,4-dioxan-2-yl, hexahydroazepin-4-yl, 3-oxa-cycloodyl, 5-thio-cyclononyl, and 2-aza-cyclodecyl.

The term “halogen atom” can refer to fluorine (F), chlorine atom (Cl), bromine atom (Br), or iodine atom (I) radical. The terms “halide” can refer to fluoride (F—), chloride (Cl—), bromide (Br—), or iodide (I—) anion.

The term “saturated” can refer to lacking carbon-carbon double bonds, carbon-carbon triple bonds, and (in heteroatom-containing groups) carbon-nitrogen, carbon-phosphorous, and carbon-silicon double bonds. Where a saturated chemical group is substituted by one or more substituents Rs, one or more double and/or triple bonds optionally may or may not be present in substituents Rs. The term “unsaturated” can refer to containing one or more carbon-carbon double bonds, carbon-carbon bonds, and (in heteroatom-containing groups) carbon-nitrogen, carbon-phosphorous, and carbon-silicon double bonds, not including any such double bonds that may be present in substituents Rs, if any, or in (hetero) aromatic rings, if any.

### First Resist Composition

In an embodiment of present disclosure, a first resist composition of a first intermediate structure 11 can be a chemically amplified photosensitive composition that can include a first polymer 41, a photoacid generator, a solvent, and may also contain additional, optional components, including a quencher. Using particular photoresist compositions of an embodiment of the present disclosure can achieve notably improved lithographic performance, such as better contrast, higher resolution, and reduced roughness of resolved patterns. For example, the first polymer 41 is an EUV photoresist in one embodiment.

### First Polymer

Next, some example materials that can be implemented and used for a first polymer 41 referenced above while describing the example embodiments of FIGS. 1A to 8, and that can be implemented and used for a first polymer 41 in other embodiments of the present disclosure, will be described.

A first polymer 41 of an embodiment of the present disclosure can be a homopolymer or a copolymer having a plurality of distinct repeat units (also referred to as monomers), for example, two, three, four, or more distinct repeat units. A first polymer 41 can be composed of monomers including vinyl aromatic monomers such as styrene, acrylate, methacrylate, norbornene, or combinations thereof, or other monomers that can be polymerized into a polymer. The repeat units of a first polymer 41 can be all formed from (meth)acrylate monomers, can be all formed from (vinyl)aromatic monomers, or can be all formed from (meth) acrylate monomers and (vinyl) aromatic monomers, for example. A first polymer 41 can include one or more monomers that include reactive functional groups including alcohols or carboxylic acids. In some embodiments, the reactive functional group can include a hydroxy-aryl group. In some embodiments, a first polymer 41 can include para-hydroxystyrene. In some embodiments, a first polymer 41 can include a carboxylic acid functionality, such as acrylic acid or methacrylic acid. In some embodiments, a first polymer 41 can include an alcohol functionality, such as 2-hydroxyethyl acrylate or 2-hydroxyethyl methacrylate or an acrylate or methacrylate functionalized with a carbohydrate selected from a group of: allose, altrose, glucose, mannose, gulose, idose, galactose, talose, psicose, fructose, sorbose, tagatose; ribose, arabinose, xylose, lyxose, ribulose, xylulose, erythose, threose, erythrulose, glyceraldehydes, altro-heptulose, L-glycero-D-manno-heptose, or a derivative thereof, for example.

A first polymer 41 can have a repeating unit having an alicyclic hydrocarbon structure and/or an aromatic ring structure that does not have a reactive functional group. In some embodiments, a first polymer 41 can include one or more monomers of Formula 1:

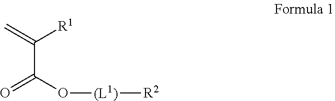

In Formula 1, R¹ can be hydrogen, fluorine, cyano, substituted or unsubstituted C₁₋₁₀ alkyl, or substituted or unsubstituted C₁₋₁₀ fluoroalkyl. In Formula 1, R¹ can be hydrogen, fluorine, or substituted or unsubstituted C₁₋₅ alkyl, typically methyl. In Formula 1, L¹ can be a single bond or a divalent linking group. For example, L¹ can be a single bond or a divalent linking group including one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₁₋₃₀ heterocycloalkylene, substituted or unsubstituted C₆₋₃₀ arylene, or substituted or unsubstituted C₄₋₃₀ heteroarylene, wherein L¹ optionally can further include one or more groups chosen, for example, from —O—, —C(O)—, —C(O)—O—, —S—, —S(O)₂—, and —N(R³)—S(O)₂—, wherein R³ can be hydrogen, substituted or unsubstituted C₁₋₂₀ alkyl, substituted or unsubstituted C₃₋₂₀ cycloalkyl, or substituted or unsubstituted C₁₋₂₀ heterocycloalkyl. In Formula 1, R² can be a monocyclic, polycyclic, or fused polycyclic C₄₋₂₀ lactone-containing group, or a monocyclic, polycyclic, or fused polycyclic C₄₋₂₀ sultone-containing group.

The total content of polymerized units comprising reactive functional groups is typically from 10 to 100 mole %, more typically from 10 to 90 mole % or from 30 to 70 mole %, based on total polymerized units of a first polymer 41 of an embodiment. In a first polymer 41 of an embodiment, the molar ratio of respective repeating structural units contained can be appropriately determined to control the dry etching resistance of photoresist, suitability for standard developer, adhesion to substrate, resist profile, and performances generally required of the photoresist, such as resolving power, heat resistance, and sensitivity, for example.

The form of a first polymer 41 in an embodiment of the present disclosure can be any form of a random type, a block type, a comb type, and a star type. When a first polymer 41 of an embodiment includes more than one type of repeat unit, it typically can take the form of a random copolymer. A first polymer 41 of an embodiment can be synthesized, for example, by polymerization of radicals, cations, or anions of an unsaturated monomer, corresponding to each structure. In an embodiment, it can be possible to obtain a target resin by using an unsaturated monomer corresponding to a precursor of each structure to perform polymerization, and then performing a polymer reaction.

A first polymer 41 in an embodiment of the present disclosure can be synthesized and purified by a suitable method (e.g., radical polymerization). Example synthesis and purification methods that can be suitable are described in paragraphs 0201 to 0202 of Japanese Patent Application Laid-Open No. 2008-292975, for example. The weight average molecular weight of a first polymer 41 in an embodiment of the present disclosure can be 7,000 or more as described above, such as in a range of 7,000 to 200,000, in a range of 7,000 to 50,000, in a range of 7,000 to 40,000, or in a range of 7,000 to 30,000, in terms of polystyrene by a Gel Permeation Chromatography (GPC) method, for example. If the weight average molecular weight is less than 7,000, the solubility in an organic developer can become higher, and thus, there can be a concern that a fine pattern can be not formed or not formed according to a given manufacturing specification.

Usually, the polydispersity (molecular weight distribution) of a first polymer 41 in an embodiment can be in a range of 1.0 to 3.0, in a range of 1.0 to 2.6, in a range of 1.0 to 2.0, or in a range of 1.4 to 2.0, for example. Generally, the smaller the molecular weight distribution is, the better the resolution and resist shape can be, and the smoother the side wall of the resist pattern can be, and thus roughness can be excellent in an embodiment of the present disclosure.

### Photoacid Generator

A photoresist composition can contain a compound capable of generating an acid upon irradiation with actinic rays or radiation (sometimes referred to as a “photoacid generator” or “PAG”). A photoacid generator which can be used may be appropriately selected from a photoinitiator for photocationic polymerization, a photoinitiator for photoradical polymerization, a photo-decoloring agent for coloring matters, a photo-discoloring agent, a known compound used for microresist, or the like, and capable of generating an acid upon irradiation with actinic rays or radiation, and mixtures thereof, for example.

A choice of PAG can be based upon such factors as acidity, catalytic activity, volatility, diffusivity, and solubility. Examples of embodied photoacid generators can include a diazonium salt, a phosphonium salt, a sulfonium salt, an iodonium salt, an imidosulfonate, an oxime sulfonate, a diazodisulfone, a disulfone, or an o-nitrobenzyl sulfonate, for example.

Suitable classes of PAGs generating sulfonic acids can include, but are not limited to, sulfonium or iodonium salts, oximidosulfonates, bissulfonyldiazomethanes, and nitrobenzylsulfonate esters, for example. A PAG can be in non-polymerized or polymeric form, for example, present in a polymerized repeating unit of the polymer matrix. Suitable photoacid generator compounds are disclosed, for example, in U.S. Pat. Nos. 5,558,978, 5,468,589, 6,844,132, 6,855,476, and 6,911,297, which are incorporated herein by reference in their entireties. In some embodiments, a preferred PAG can include one or more of tris(perfluoroalkylsulfonyl)methides, tris(perfluoroalkylsulfonyl)imides, and those generating perfluoroalkylsulfonic acids, for example.

Additional examples of suitable photoacid generators can include, but are not limited to, triphenylsulfonium perfluorooctanesulfonate, triphenylsulfonium perfluorobutanesulfonate, methylphenyldiphenylsulfonium perfluorooctanesulfonate, 4-n-butoxyphenyldiphenylsulfonium perfluorobutanesulfonate, 2,4,6-trimethylphenyldiphenylsulfonium perfluorobutanesulfonate, 2,4,6-trimethylphenyldiphenylsulfonium benzenesulfonate, 2,4,6-trimethylphenyldiphenylsulfonium 2,4,6-triisopropylbenzenesulfonate, phenylthiophenyldiphenylsulfonium 4-dodecylbenzensulfonic acid, tris(-t-butylphenyl)sulfonium perfluorooctanesulfonate, tris(-t-butylphenyl)sulfonium perfluorobutanesulfonate, tris(-t-butylphenyl)sulfonium 2,4,6-triisopropylbenzenesulfonate, tris(-t-butylphenyl)sulfonium benzenesulfonate, and phenylthiophenyldiphenylsulfonium perfluorooctanesulfonate.

Examples of suitable iodonium salts can include, but are not limited to, diphenyl iodonium perfluorobutanesulfonate, bis-(t-butylphenyl)iodonium perfluorobutanesulfonate, bis-(t-butylphenyl)iodonium, perfluorooctanesulfonate, diphenyl iodonium perfluorooctanesulfonate, bis-(t-butylphenyl)iodonium benzenesulfonate, bis-(t-butylphenyl)iodonium 2,4,6-triisopropylbenzenesulfonate, and diphenyliodonium 4-methoxybenzensulfonate.

Examples of tris(perfluoroalkylsulfonyl)methide and tris(perfluoroalkylsulfonyl)imide PAGs can be found in U.S. Pat. Nos. 5,554,664 and 6,306,555, each of which is incorporated herein in its entirety. For an SSA of an embodiment, additional examples of PAGs of this type can be found in Proceedings of SPIE, Vol. 4690, pp. 817-828 (2002).

Suitable methide and imide PAGs can include, but are not limited to, triphenylsulfonium tris(trifluoromethylsulfonyl)methide, methylphenyldiphenylsulfonium tris(perfluoroethylsulfonyl)methide, triphenylsulfonium tris(perfluorobutylsulfonyl)methide, triphenylsulfonium bis(trifluoromethylsulfonyl)imide, triphenylsulfonium bis(perfluoroethylsulfonyl)imide, and triphenylsulfonium bis(perfluorobutylsulfonyl)imide.

Further examples of suitable photoacid generators can be bis(p-toluenesulfonyl)diazomethane, methylsulfonyl p-toluenesulfonyldiazomethane, 1-cyclo-hexylsulfonyl-1-(1,1-dimethylethylsulfonyl)diazomethane, bis(1,1-dimethylethylsulfonyl)diazomethane, bis(i-methylethylsulfonyl)diazomethane, bis(cyclohexylsulfonyl)diazomethane, 1-p-toluenesulfonyl-1-cyclohexylcarbonyldiazomethane, 2-methyl-2-(p-toluenesulfonyl)propiophenone, 2-methanesulfonyl-2-methyl-(4-methylthiopropiophenone, 2,4-methyl-2-(p-toluenesulfonyl)pent-3-one, 1-diazo-1-methylsulfonyl-4-phenyl-2-butanone, 2-(cyclohexylcarbonyl-2-(p-toluenesulfonyl)propane, 1-cyclohexylsulfonyl-icyclohexylcarbonyldiazomethane, 1-diazo-1-cyclohexylsulfonyl-3,3-dimethyl-2-butanone, 1-diazo-1-(1,1-dimethylethylsulfonyl)-3,3-dimethyl-2-butanone, 1-acetyl-1-(i-methylethylsulfonyl)diazomethane, 1-diazo-1-(p-toluenesulfonyl)-3,3-dimethyl-2-butanone, 1-diazo-1-benzenesulfonyl-3,3-dimethyl-2-butanone, 1-diazo-1-(p-toluenesulfonyl)-3-methyl-2-butanone, cyclohexyl 2-diazo-2-(p-toluenesulfonyl)acetate, tert-butyl 2-diazo-2-benzenesulfonylacetate, isopropyl-2-diazo-2-methanesulfonylacetate, cyclohexyl 2-diazo-2-benzenesulfonylacetate, tert-butyl 2 diazo-2-(p-toluenesulfonyl)acetate, 2-nitrobenzyl p-toluenesulfonate, 2,6-dinitrobenzyl p-toluenesulfonate, and 2,4-dinitrobenzyl p-trifluoromethylbenzenesulfonate.

Some more preferred PAGs can be triarylsulfonium perfluoroalkylsulfonates and triarylsulfonium tris(perfluoroalkylsulfonyl)methides. For an SSA of an embodiment, some more preferred PAGs can include triphenylsulfonium perfluorooctanesulfonate (TPS-PFOS), triphenylsulfonium perfluorobutanesulfonate (TPS-Nonaflate), methyiphenyldiphenylsulfonium perfluorooctanesulfonate (TDPS-PFOS), tris(-t-butylphenyl)sulfonium perfluorobutanesulfonate (TTBPS-Nonaflate), triphenylsulfonium tris(trifluoromethylsulfonyl)methide (TPS-C1), or methylphenyldiphenylsulfonium tris(perfluoroethylsulfonyl)methide.

Additional PAG compounds can include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, or di-t-butyphenyliodonium camphorsulfonate.

Non-ionic sulfonates and sulfonyl compounds can function as photoacid generators, for example: nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; or halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine.

Suitable non-polymerized photoacid generators that can be used are further described in U.S. Pat. No. 8,431,325 to Hashimoto et al. in column 37, lines 11-47 and columns 41-91. For an SSA of an embodiment, other suitable sulfonate PAGs can include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Pat. Nos. 4,189,323 and 8,431,325. PAGs that are onium salts typically can include an anion having a sulfonate group or a non-sulfonate type group, such as a sulfonamidate group, a sulfonimidate group, a methide group, or a borate group.

A photoresist composition may optionally include a plurality of PAGs. The plural PAGs can be polymeric, non-polymeric, or can include both polymeric and non-polymeric PAGs. In some embodiments, each of the plurality of PAGs can be non-polymeric. In some embodiments, when a plurality of PAGs are used, a first PAG can include a sulfonate group on the anion and a second PAG can include an anion that is free of sulfonate groups, such anion containing for example, a sulfonamidate group, a sulfonimidate group, a methide group, or a borate group, such as described above, for example.

In some embodiments, the PAG can be a polymeric PAG, wherein the compound capable of generating an acid upon irradiation with actinic rays or radiation is introduced into the main or side chain of the polymer. For an SSA of an embodiment, examples can include, for example, compounds described in U.S. Pat. No. 3,849,137, German Patent 3,914,407, JP-A-63-26653, JP-A-55-164824, JP-A-62-69263, JP-A-63-146038, JP-A-63-163452, JP-A-62-153853, and JP-A-63-146029.

In some embodiments, a photoresist composition can include a non-polymerized photoacid generator in an amount from about 1 to 65 wt %, from about 5 to 55 wt %, or from about 8 to 30 wt %, based on total solids of the photoresist composition, for example. In some embodiments, a photoresist composition can include two or more different non-polymerized photoacid generators in a combined amount from about 1 to 65 wt %, from about 5 to 55 wt %, or from about 8 to 30 wt %, based on total solids of the photoresist composition, for example. In some embodiments, a photoacid generator mixture can include two or three photoacid generators. Such mixtures can be of a same class or different classes. Examples of some preferred mixtures can include sulfonium salts with bis-sulfonyldiazomethane compounds, sulfonium salts and imidosulfonates, and two sulfonium salts, for example.

### Solvent

Before deposition and/or at the time of deposition, a photoresist composition in an embodiment of the present disclosure can further include a solvent for dissolving the components of the composition and facilitating its coating on a substrate, and most of or all of the solvent can be evaporated during the deposition operation, for example. Preferably, the solvent can be an organic solvent conventionally used in the manufacture of electronic devices. Suitable solvents can include, for example: aliphatic hydrocarbons such as hexane and heptane; aromatic hydrocarbons such as toluene and xylene; halogenated hydrocarbons such as dichloromethane, 1,2-dichloroethane and 1-chlorohexane; alcohols such as methanol, ethanol, 1-propanol, iso-propanol, tert-butanol, 2-methyl-2-butanol and 4-methyl-2-pentanol; propylene glycol monomethyl ether (PGME), ethers such as diethyl ether, tetrahydrofuran, 1,4-dioxane and anisole; ketones such as acetone, methyl ethyl ketone, methyl iso-butyl ketone, 2-heptanone and cyclohexanone (CHO); esters such as ethyl acetate, n-butyl acetate, propylene glycol monomethyl ether acetate (PGMEA), ethyl lactate (EL), hydroxyisobutyrate methyl ester (HBM) and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; water; or any combination thereof. Of these, preferred solvents can be PGME, PGMEA, EL, GBL, HBM, CHO, or any combination thereof. The total solvent content (i.e., cumulative solvent content for all solvents) in the photoresist compositions is typically from 40 to 99 wt %, more typically from 70 to 99 wt %, and still more typically from 85 to 99 wt %, based on total weight of the photoresist composition, for example. The desired solvent content can depend, for example, on the desired thickness of the coated photoresist layer and coating conditions.

### Quencher

In some embodiments, a quencher base or base generator can be included in the first intermediate structure 11 to help control diffusion of an active material in/of the SSA 15. For an embodiment, suitable quencher base or base generators can include, but are not limited to, hydroxides, carboxylates, amines, imines, amides, or mixtures thereof. Specific examples of bases can include ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, or combinations thereof. Amines can include aliphatic amines, cycloaliphatic amines, aromatic amines, or heterocyclic amines. The amine can be a primary, secondary, or tertiary amine. The amine can be a monoamine, diamine, or polyamine. Suitable amines can include C-30 organic amines, imines, or amides, or may be a C-30 quaternary ammonium salt of a strong base (e.g., a hydroxide or alkoxide) or a weak base (e.g., a carboxylate). In some embodiments, example bases can include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl)propane, Troger's base, a hindered amine such as diazabicycloundecene (DBU) or diazabicyclononene (DBN), amides like tert-butyl 1,3-dihydroxy-2-(hydroxymethyl)propan-2-ylcarbamate and tert-butyl 4-hydroxypiperidine-l-carboxylateor; or ionic quenchers including quaternary alkyl ammonium salts such as tetrabutylammonium hydroxide (TBAH) or tetrabutylammonium lactate.

In some embodiments, the amine can be a hydroxyamine. Examples of hydroxyamines can include hydroxyamines having one or more hydroxyalkyl groups each having 1 to about 8 carbon atoms, and sometimes preferably 1 to about 5 carbon atoms such as hydroxymethyl, hydroxyethyl and hydroxybutyl groups. Specific examples of hydroxy amines can include mono-, di- and tri-ethanolamine, 3-amino-1-propanol, 2-amino-2-methyl-1-propanol, 2-amino-2-ethyl-1,3-propanediol, tris(hydroxymethyl)aminomethane, N-methylethanolamine, 2-diethylamino-2-methyl-1-propanol, and triethanolamine.

In an embodiment, suitable base generators can be thermal base generators. A thermal base generator (TAG) can form a base upon heating above a first temperature, typically about 140° C. or higher. The thermal base generator can include a functional group such as an amide, sulfonamide, imide, imine, O-acyl oxime, benzoyloxycarbonyl derivative, quarternary ammonium salt, nifedipine, carbamate, or combinations thereof, for example.

In an embodiment, example thermal base generators can include:
o-{β-(dimethylamino)ethyl)aminocarbonyl}benzoic acid,
o-{(γ-(dimethylamino)propyl)aminocarbonyl}benzoic acid,
2,5-bis{(β-(dimethylamino)ethyl)aminocarbonyl}terephthalic acid,
2,5-bis {(γ-(dimethylamino)propyl)aminocarbonyl}terephthalic acid,
2,4-bis{(β-(dimethylamino)ethyl)aminocarbonyl}isophthalic acid,
2,4-bis{(γ-(dimethylamino)propyl)aminocarbonyl]isophthalic acid, or combinations thereof, for example.

A quencher base or base generator can be in non-polymeric or polymer-bound form. When in polymeric form, a quencher can be present in polymerized units on the polymer. The polymerized units containing the quencher can be typically present in an amount of from 0.1 to 30 mole %, preferably from 1 to 10 mole %, and more preferably from 1 to 2 mole %, based on total repeating units of the polymer.

### Optional Additives

In an embodiment, the photoresist compositions described above may further include one or more additional, optional additives. For example, optional additives may include actinic and contrast dyes, anti-striation agents, plasticizers, speed enhancers, sensitizers, photo-decomposable quenchers (also known as photo-decomposable bases), basic quenchers, surfactants, and the like, or combinations thereof. If present, the optional additives can be typically present in the photoresist compositions in an amount from 0.01 to 10 wt %, based on total solids of the photoresist composition.

Photo-decomposable quenchers can generate a weak acid upon irradiation. The acid generated from a photo-decomposable quencher can be not strong enough to react rapidly with acid-labile groups that are present in the resist matrix. Example photo-decomposable quenchers can include, for example, photo-decomposable cations, and can be preferably those also useful for preparing strong acid generator compounds, paired with an anion of a weak acid (pKa>-1) such as, for example, an anion of a C1-20 carboxylic acid or C1-20 sulfonic acid.

Example carboxylic acids can include formic acid, acetic acid, propionic acid, tartaric acid, succinic acid, cyclohexanecarboxylic acid, benzoic acid, salicylic acid, and the like. Example sulfonic acids can include p-toluene sulfonic acid, camphor sulfonic acid and the like. In some embodiments, the photo-decomposable quencher can be a photo-decomposable organic zwitterion compound such as diphenyliodonium-2-carboxylate.

The photo-decomposable quencher can be in non-polymeric or polymer-bound form. When in polymeric form, the photo-decomposable quencher can be present in polymerized units on the first polymer or second polymer. The polymerized units containing the photo-decomposable quencher can be typically present in an amount from 0.1 to 30 mole %, sometimes preferably from 1 to 10 mole %, and sometimes more preferably from 1 to 2 mole %, based on total repeating units of the polymer.

Example basic quenchers can include, for example: linear aliphatic amines such as tributylamine, trioctylamine, triisopropanolamine, tetrakis(2-hydroxypropyl)ethylenediamine:n-tert-butyldiethanolamine, tris(2-acetoxy-ethyl) amine, 2,2′,2″,2′″-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, di-tert-butyl pyridine, and pyridinium; linear and cyclic amides and derivatives thereof such as N,N-bis(2-hydroxyethyl)pivalamide, N,N-diethylacetamide, N1,N1,N3,N3-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; or optionally substituted pyrrolidones such as 2-pyrrolidone and cyclohexyl pyrrolidine.

The basic quenchers can be in non-polymeric or polymer-bound form. When in polymeric form, the quencher can be present in polymerized units on the polymer. The polymerized units containing the quencher can be typically present in an amount of from 0.1 to 30 mole %, sometimes preferably from 1 to 10 mole %, and sometimes more preferably from 1 to 2 mole %, based on total repeating units of the polymer.

Example surfactants can include fluorinated and non-fluorinated surfactants and can be ionic or non-ionic, with non-ionic surfactants being sometimes preferable. Example fluorinated non-ionic surfactants can include perfluoro C4 surfactants such as FC-4430 and FC-4432 surfactants, available from 3M Corporation; and fluorodiols such as POLYFOX PF-636, PF-6320, PF-656, and PF-6520 fluorosurfactants from Omnova. In some embodiments, the photoresist composition can further include a surfactant polymer including a fluorine-containing repeating unit.

### Overcoat Composition

In an embodiment of present disclosure, an overcoat resist composition may be used to form an overcoat layer 25. The overcoat resist composition can include a matrix polymer, a solubility shifting agent, a solvent, and may also contain additional, optional components.

### Matrix Polymer

Any matrix polymer commonly used in the art may be included in the solubility-shifting material. The matrix polymer should have good solubility in a solvent that does not dissolve the first resist. The matrix polymer can be formed from one or more monomers chosen, for example, from those having an ethylenically unsaturated polymerizable double bond, such as: (meth)acrylate monomers such as isopropyl(meth)acrylate and n-butyl(meth)acrylate; (meth)acrylic acid; vinyl aromatic monomers such as styrene, hydroxystyrene, vinyl naphthalene and acenaphthylene; vinyl alcohol; vinyl chloride; vinyl pyrrolidone; vinyl pyridine; vinyl amine; vinyl acetal; maleic anhydride; maleimides; norbomenes; and combinations thereof.

In some embodiments, the matrix polymer contains one or more functional groups chosen, for example, from hydroxy, acid groups such as carboxyl, sulfonic acid and sulfonamide, silanol, fluoroalcohol such as hexafluoroisopropyl alcohol [—C(CF3)2OH], anhydrates, lactones, esters, ethers, allylamine, pyrrolidones and combinations thereof. The matrix polymer can be a homopolymer or a copolymer having a plurality of distinct repeat units, for example, two, three, four or more distinct repeat units. In one aspect, the repeat units of the matrix polymer are all formed from (meth)acrylate monomers, are all formed from (vinyl)aromatic monomers or are all formed from (meth) acrylate monomers and (vinyl) aromatic monomers. When the matrix polymer includes more than one type of repeat unit, it typically takes the form of a random copolymer.

In particular embodiments, the matrix polymer may be a t-butyl acrylate (TBA)/p-hydroxystyrene (PHS) copolymer, a butyl acrylate (BA)/PHS copolymer, a TBA/methacrylic acid (MAA) copolymer, a BA/MAA copolymer, a PHS/methacrylate (MA) copolymer, and combinations thereof.

The overcoat compositions typically include a single polymer but can optionally include one or more additional polymers. The content of the matrix polymer in the composition will depend, for example, on the target thickness of the layer, with a higher polymer content being used when a thicker layer is desired. The matrix polymer is typically present in the overcoat composition in an amount of from 80 to 99.9 wt %, more typically from 90 to 99 wt %, or 95 to 99 wt %, based on total solids of the overcoat compositions. The weight average molecular weight (Mw) of the polymer is typically less than 400,000, preferably from 3000 to 50,000, more preferably from 3000 to 25,000, as measured by GPC versus polystyrene standards. Typically, the matrix polymer will have a polydispersity index (PDI=Mw/Mn) of 3 or less, preferably 2 or less, as measured by GPC versus polystyrene standards.

Suitable matrix polymers for use in the overcoat compositions are commercially available and/or can readily be made by persons skilled in the art. For example, the matrix polymer may be synthesized by dissolving selected monomers corresponding to units of the matrix polymer in an organic solvent, adding a radical polymerization initiator thereto, and effecting heat polymerization to form the polymer. Examples of suitable organic solvents that can be used for polymerization of the polymer include, for example, toluene, benzene, tetrahydrofuran, diethyl ether, dioxane, ethyl lactate and methyl isobutyl carbinol. Suitable polymerization initiators include, for example, 2,2′-azobisisobutyronitrile (AIBN), 2,2′-azobis(2,4-dimethylvaleronitrile), dimethyl 2,2-azobis(2-methylpropionate), benzoyl peroxide and lauroyl peroxide.

In one or more embodiments, an overcoat composition includes an active material (z.e., an acid, acid generator, base, or base generator), a solvent, and a matrix polymer as previously described. A typical formulation for such overcoat composition may include about 1 to 10 wt % solids and 90 to 99 wt % solvent, based on the total weight of the overcoat composition, where the solids include the active material and the matrix polymer. Within the solids content, the active material may be included in an amount ranging from about 1 to about 5 wt %.

### Solubility Shifting Agents

Next, some example materials that can be implemented and used for a first SSA 15 (solubility shifting agent) or a second SSA 315 referenced above while describing the example embodiments of FIGS. 1A to 8, and that can be implemented and used for a first SSA 15 or a second SSA 315 in other embodiments of the present disclosure, will be described.

An SSA of an embodiment of the present disclosure can include a thermal-acid generator (TAG) that is configured to generate an acid in response to heat and/or a photo-acid generator (PAG) that is configured to generate an acid in response to actinic radiation, for example. In an embodiment, the SSA can include an acid or an acid generator such as a TAG or PAG, for example.

In an embodiment, an SSA can include multiple solubility shifting agents combined, such as multiple PAGs, multiple TAGs, or one or more PAGs combined with one or more TAGs, or any combination thereof with an already free acid, for example.

### Solubility Shifting Agent as a Free Acid

In some embodiments, an SSA can be an acid that is an organic acid, which can include both non-aromatic acids and aromatic acids optionally having fluorine substitution. Suitable organic acids for an SSA of an embodiment can include: carboxylic acids and polycarboxylic acids such as alkanoic acids, including formic acid, acetic acid, propionic acid, butyric acid, dichloroacetic acid, trichloroacetic acid, perfluoroacetic acid, perfluorooctanoic acid, oxalic acid malonic acid and succinic acid; hydroxyalkanoic acids, such as citric acid; aromatic carboxylic acids such as benzoic acid, fluorobenzoic acid, hydroxybenzoic acid, and naphthoic acid; organic phosphorus acids such as dimethylphosphoric acid and dimethylphosphinic acid; and sulfonic acids such as optionally fluorinated alkylsulfonic acids including methanesulfonic acid, trifluoromethanesulfonic acid, ethanesulfonic acid, 1-butanesulfonic acid, 1-perfluorobutanesulfonic acid, 1,1,2,2-tetrafluorobutane-1-sulfonic acid, 1,1,2,2-tetrafluoro-4-hydroxybutane-1-sulfonic acid, 1-pentanesulfonic acid, 1-hexanesulfonic acid, and 1-heptanesulfonic acid; or any combination thereof, for example.

In some embodiments, an SSA can be an aromatic sulfonic acid. For example, an aromatic sulfonic acid can be of general Formula 4:

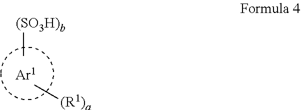

In Formula 4, Ar¹ can represent an aromatic group, which can be carbocyclic, heterocyclic, or a combination thereof. The aromatic group can be monocyclic, for example, phenyl or pyridyl, or polycyclic, for example biphenyl, and can include: plural fused aromatic rings such as naphthyl, anthracenyl, pyrenyl, or quinolinyl; or fused ring systems having both aromatic and non-aromatic rings such as 1,2,3,4-tetrahydronaphthalene, 9,10-dihydroanthracene or fluorene. A wide variety of aromatic groups may be used for Ar¹. The aromatic group typically can have from 5 to 40 carbons, preferably from 6 to 35 carbons, and more preferably from 6 to 30 carbons. Suitable aromatic groups can include, but are not limited to: phenyl, biphenyl, naphthalenyl, anthracenyl, phenanthrenyl, pyrenyl, tetracenyl, triphenylenyl, tetraphenyl, benzo[f]tetraphenyl, benzo[m]tetraphenyl, benzo[k]tetraphenyl, pentacenyl, perylenyl, benzo[a]pyrenyl, benzo[e]pyrenyl, benzo[ghi]perylenyl, coronenyl, quinolonyl, 7,8-benzoquinolinyl, fluorenyl, and 12H-dibenzo[b,h]fluorenyl. Of these, phenyl can be particularly preferred.

In Formula 4, R¹ independently can represent a halogen atom, hydroxy, substituted or unsubstituted alkyl, substituted or unsubstituted heteroalkyl, substituted or unsubstituted carbocyclic aryl, substituted or unsubstituted heterocyclic aryl, substituted or unsubstituted alkoxy, or a combination thereof. R¹ can also include one or more groups such as ester, carboxy, ether, or a combination thereof.

In Formula 4, “a” can represent an integer of o or more and “b” can represent an integer of 1 or more, provided that a+b is not greater than the total number of available aromatic carbon atoms of Ar¹. Preferably, two or more of R¹ can be independently a fluorine atom or a fluoroalkyl group bonded directly to an aromatic ring carbon atom.

The aromatic acid can be a sulfonic acid including a phenyl, biphenyl, naphthyl, anthracenyl, thiophene or furan group. The aromatic acid can be chosen from one or more aromatic sulfonic acids of the following general Formulas 5-10:

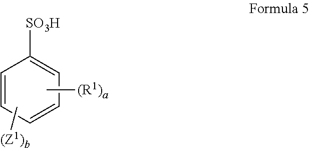

In Formula 5, R¹ can independently represent a substituted or unsubstituted C1-C20 alkyl group, a substituted or unsubstituted C5-C20 aryl group, or a combination thereof, optionally containing one or more group chosen from carbonyl, carbonyloxy, sulfonamido, ether, thioether, a substituted or unsubstituted alkylene group, or a combination thereof.

In Formula 5, Z¹ can independently represent a group chosen from carboxyl, hydroxy, nitro, cyano, C₁ to C₅ alkoxy, formyl and sulfonic acid. In Formula 5, “a” and “b” can be independently an integer from 0 to 5, and a+b can be 5 or less.

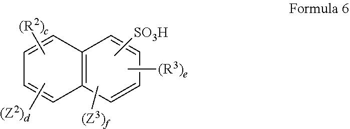

In Formula 6, R² and R³ each can independently represent a substituted or unsubstituted C1-C20 alkyl group, a substituted or unsubstituted C5-C16 aryl group, or a combination thereof, optionally containing one or more group chosen from carbonyl, carbonyloxy, sulfonamido, ether, thioether, a substituted or unsubstituted alkylene group, or a combination thereof.

In Formula 6, Z² and Z³ each can independently represent a group chosen from carboxyl, hydroxy, nitro, cyano, C₁ to C₅ alkoxy, formyl and sulfonic acid. In Formula 6, “c” and “d” can be independently an integer from 0 to 4, c+d can be 4 or less, “e” and “f” can be independently an integer from 0 to 3, and e+f can be 3 or less.

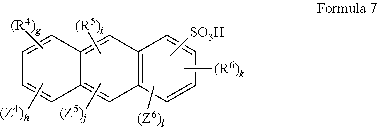

In Formula 7, R⁴, R⁵ and R⁶ each can independently represent a substituted or unsubstituted C1-C20 alkyl group, a substituted or unsubstituted C5-C12 aryl group, or a combination thereof, optionally containing one or more group chosen from carbonyl, carbonyloxy, sulfonamido, ether, thioether, a substituted or unsubstituted alkylene group, or a combination thereof.

In Formula 7, Z⁴, Z⁵ and Z⁶ each can independently represent a group chosen from carboxyl, hydroxy, nitro, cyano, C1 to C5 alkoxy, formyl and sulfonic acid. In Formula 7, “g” and “h” can be independently an integer from 0 to 4, g+h can be 4 or less, “i” and “j” can be independently an integer from 0 to 2, i+j can be 2 or less, “k” and “l” can be independently an integer from 0 to 3, and k+l can be 3 or less.

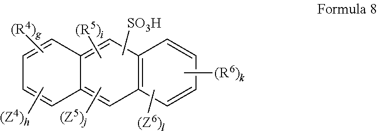

In Formula 8, R⁴, R⁵ and R⁶ each can independently represent a substituted or unsubstituted C1-C20 alkyl group, a substituted or unsubstituted C5-C12 aryl group, or a combination thereof, optionally containing one or more group chosen from carbonyl, carbonyloxy, sulfonamido, ether, thioether, a substituted or unsubstituted alkylene group, or a combination thereof.

In Formula 8, Z⁴, Z⁵ and Z⁶ each can independently represent a group chosen from carboxyl, hydroxy, nitro, cyano, C₁ to C₅ alkoxy, formyl and sulfonic acid. In Formula 8, “g” and “h” can be independently an integer from 0 to 4, g+h can be 4 or less, “i” and “j” can be independently an integer from 0 to 1, i+j can be 1 or less, “k” and “l” can be independently an integer from 0 to 4, and k+l can be 4 or less.

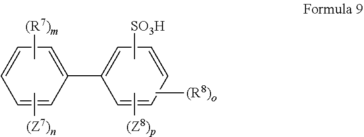

In Formula 9, R⁷ and R⁸ each can independently represent a substituted or unsubstituted C₁-C₂₀ alkyl group, a substituted or unsubstituted C₅-C₁₄ aryl group, or a combination thereof, optionally containing one or more group chosen from carboxyl, carbonyl, carbonyloxy, sulfonamido, ether, thioether, a substituted or unsubstituted alkylene group, or a combination thereof.

In Formula 9, Z⁷ and Z⁸ each can independently represent a group chosen from hydroxy, nitro, cyano, C₁ to C₅ alkoxy, formyl and sulfonic acid. In Formula 9, “m” and “n” can be independently an integer from 0 to 5, m+n can be 5 or less, “o” and “p” can be independently an integer from 0 to 4, and o+p can be 4 or less.

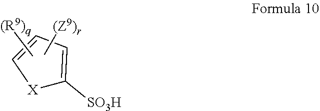

In Formula 10, X can be O or S. In Formula 10, R⁹ can independently represent a substituted or unsubstituted C₁-C₂₀ alkyl group, a substituted or unsubstituted C₅-C₂₀ aryl group, or a combination thereof, optionally containing one or more group chosen from carbonyl, carbonyloxy, sulfonamido, ether, thioether, a substituted or unsubstituted alkylene group, or a combination thereof.

In Formula 10, Z⁹ can independently represent a group chosen from carboxyl, hydroxy, nitro, cyano, C₁ to C₅ alkoxy, formyl and sulfonic acid. In Formula 10, “q” and “r” can be independently an integer from 0 to 3, and q+r can be 3 or less.

For each of the structures of Formulas 5-10, the R¹-R⁹ groups can optionally form a fused structure together with their respective associated rings, for example.

For an SSA of an embodiment, example aromatic sulfonic acids can include, without limitation, the following:

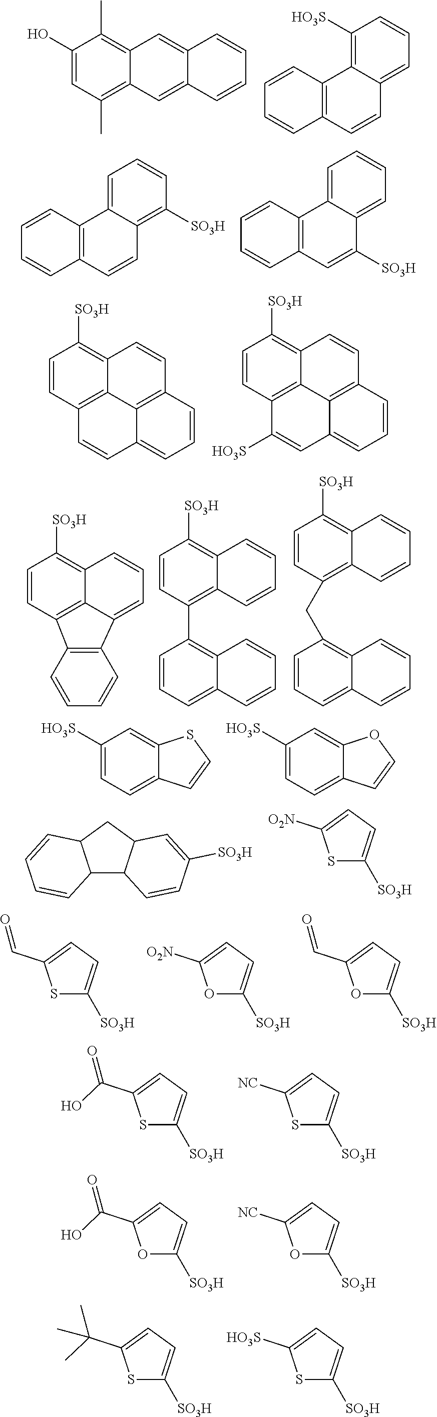

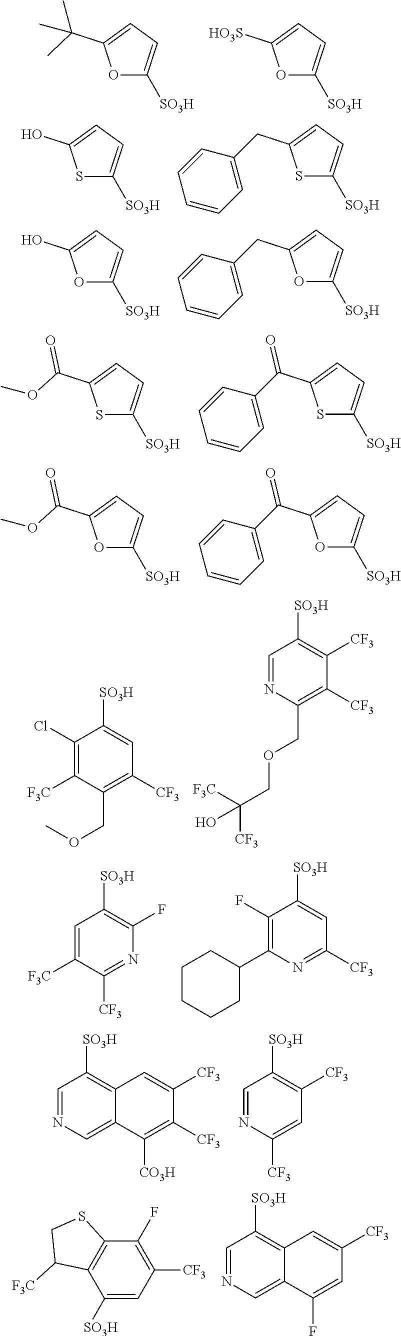

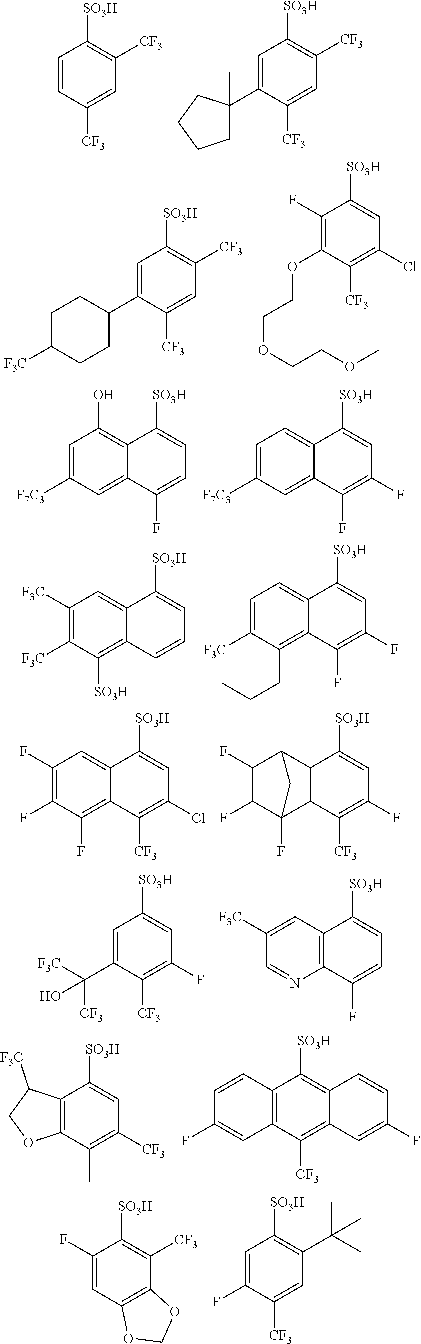

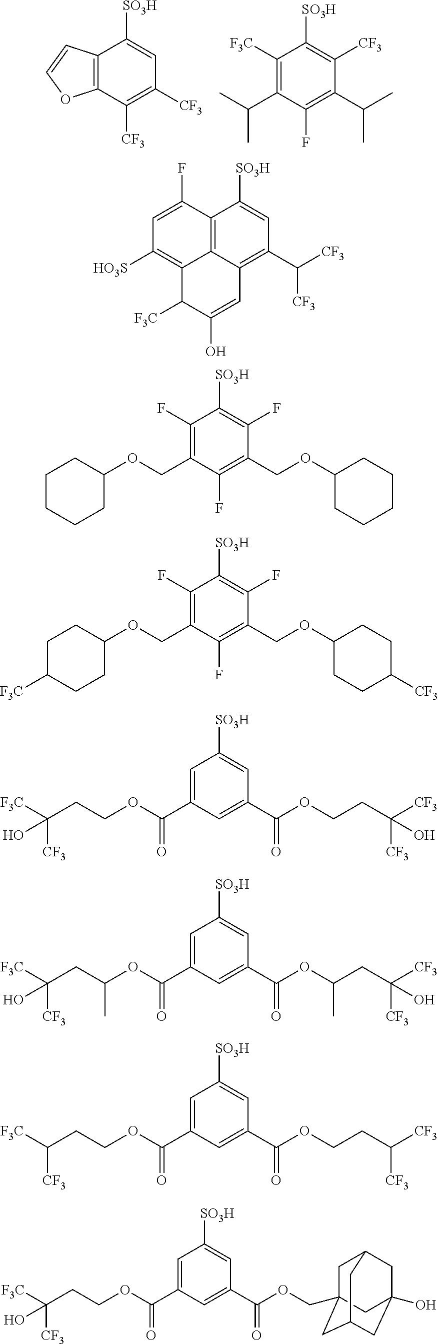

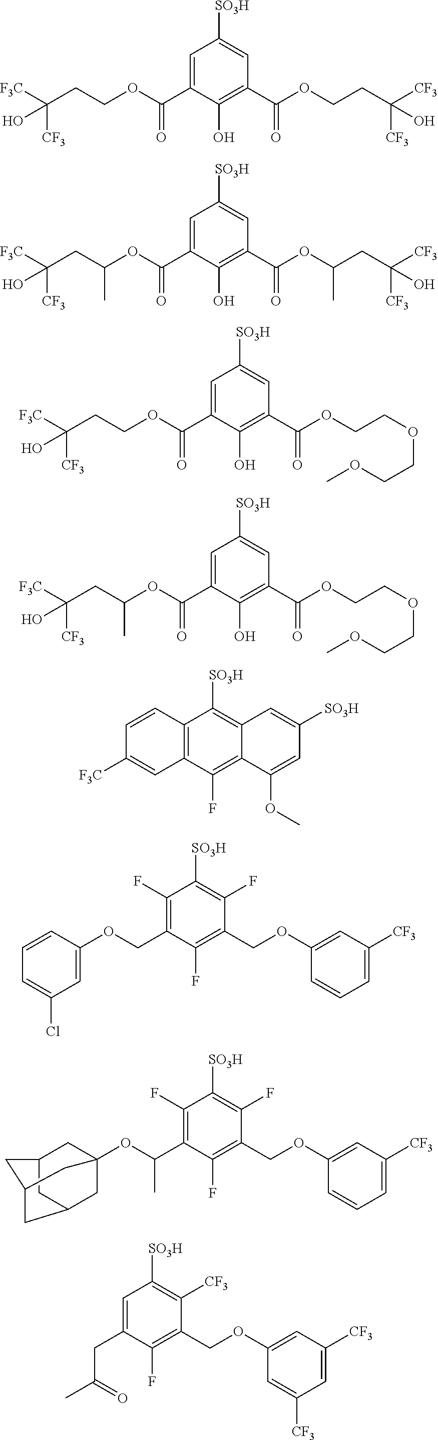

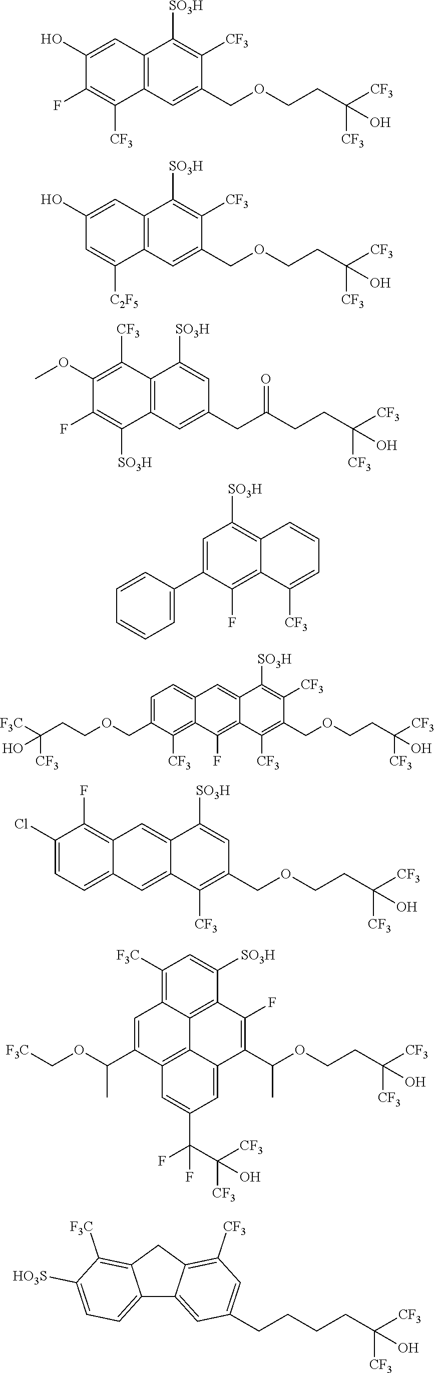

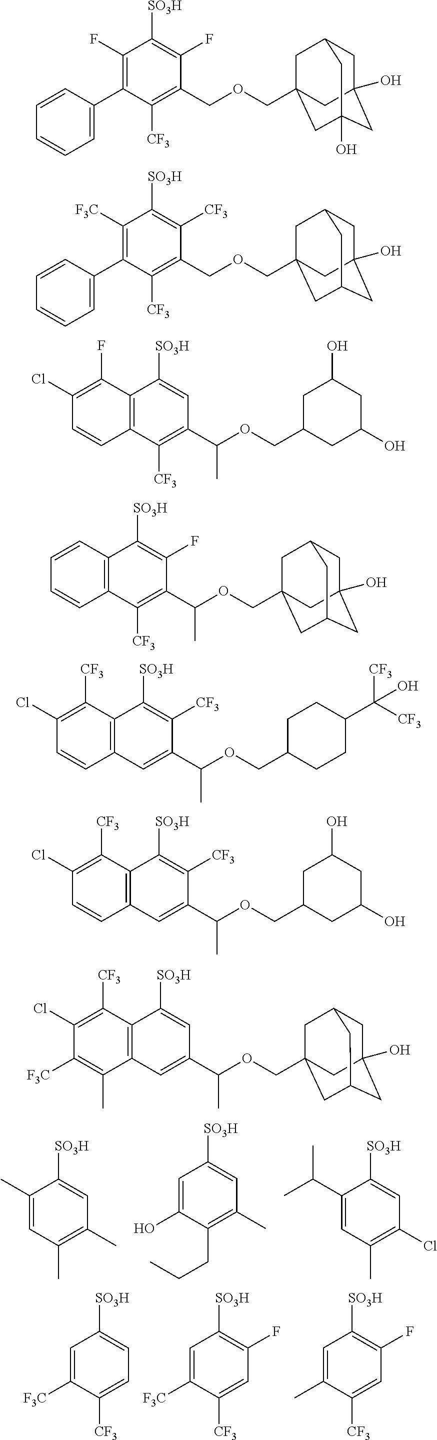

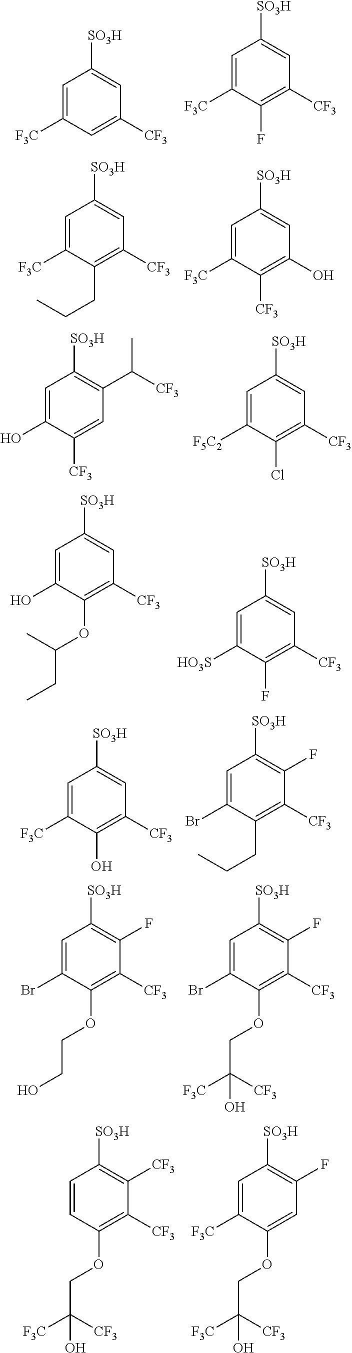

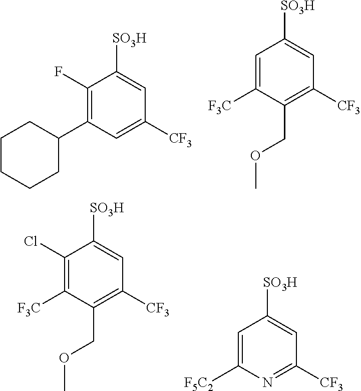

For an SSA of an embodiment, example non-aromatic sulfonic acids can include, without limitation, the following:

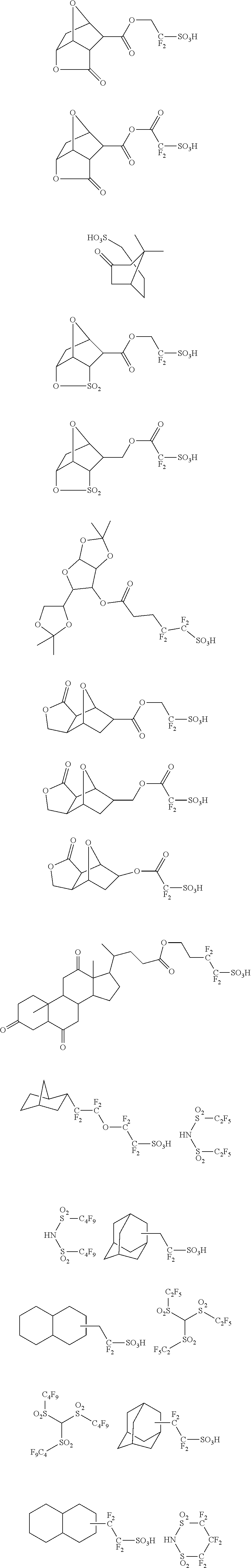

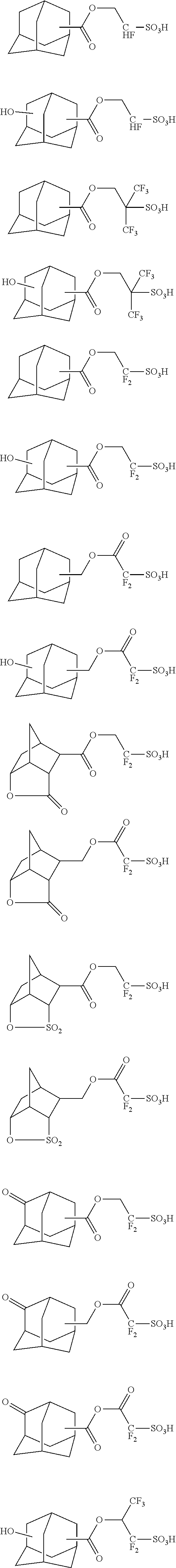

### Solubility Shifting Agent as Thermal Acid Generator (TAG)

For an SSA of an embodiment, suitable thermal acid generators can include those capable of generating the acids described above. The thermal acid generator (TAG) can be non-ionic or ionic.

For an SSA of an embodiment, suitable nonionic thermal acid generators can include, for example, cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-l, 3, 5-triazine-2, 4, 6-trione, alkyl esters of organic sulfonic acids, p-toluenesulfonic acid, dodecylbenzenesulfonic acid, oxalic acid, phthalic acid, phosphoric acid, camphorsulfonic acid, 2,4,6-trimethylbenzene sulfonic acid, triisopropylnaphthalene sulfonic acid, 5-nitro-o- toluene sulfonic acid, 5-sulfosalicylic acid, 2,5-dimethylbenzene sulfonic acid, 2-nitrobenzene sulfonic acid, 3-chlorobenzene sulfonic acid, 3-bromobenzene sulfonic acid, 2-fluorocaprylnaphthalene sulfonic acid, dodecylbenzene sulfonic acid, 1-naphthol-5-sulfonic acid, 2-methoxy-4-hydroxy-5-benzoyl-benzene sulfonic acid, or their salts, or combinations thereof.

For an SSA of an embodiment, suitable ionic thermal acid generators can include, for example, dodecylbenzenesulfonic acid triethylamine salts, dodecylbenzenedisulfonic acid triethylamine salts, p-toluene sulfonic acid-ammonium salts, p-toluene sulfonic acid-pyridinium salts, sulfonate salts, such as carbocyclic aryl and heteroaryl sulfonate salts, aliphatic sulfonate salts, or benzenesulfonate salts, or combinations thereof. Compounds that can generate a sulfonic acid upon activation can be generally suitable as a TAG for an SSA of an embodiment, for example. For an SSA of an embodiment, some preferred thermal acid generators can include p-toluenesulfonic acid ammonium salts and heteroaryl sulfonate salts, for example.

For example, for an SSA of an embodiment, the TAG can be preferably ionic with a reaction scheme for generation of a sulfonic acid as shown below:

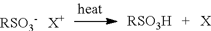

wherein RSO₃⁻ can be the TAG anion and X⁺ can be the TAG cation, preferably an organic cation. The cation can be a nitrogen-containing cation of the general Formula 11:

(BH)⁺ Formula 11

Formula 11 can be the monoprotonated form of a nitrogen-containing base B. In Formula 11, suitable nitrogen-containing bases B can include, for example: optionally substituted amines such as ammonia, difluoromethylammonia, C1-20 alkyl amines, and C₃₋₃₀ aryl amines, for example, nitrogen-containing heteroaromatic bases such as pyridine or substituted pyridine (e.g., 3-fluoropyridine), pyrimidine and pyrazine; and nitrogen-containing heterocyclic groups, for example, oxazole, oxazoline, or thiazoline. The foregoing nitrogen-containing bases B can be optionally substituted, for example, with one or more group chosen from alkyl, aryl, halogen atom (preferably fluorine), cyano, nitro and alkoxy. Of these, base B can be preferably a heteroaromatic base.

Base B typically can have a pKₐ from 0 to 5.0, or between 0 and 4.0, or between 0 and 3.0, or between 1.0 and 3.0. As used herein, the term “pKₐ” is used in accordance with its art-recognized meaning, that is, pKₐ can be the negative log (to the base 10) of the dissociation constant of the conjugate acid (BH)⁺ of the basic moiety (B) in aqueous solution at about room temperature. In certain embodiments, base B can have a boiling point less than about 170° C., or less than about 160° C., 150° C., 140° C., 130° C., 120° C., 110° C., 100° C., or 90° C.

For an SSA of an embodiment, example suitable nitrogen-containing cations (BH)⁺ can include NH₄⁺, CF₂HNH₂⁺, CF₃CH₂NH₃⁺, (CH₃)₃NH⁺, (C₂H₅)₃NH⁺, (CH₃)₂(C₂H₅)NH⁺ and the following:

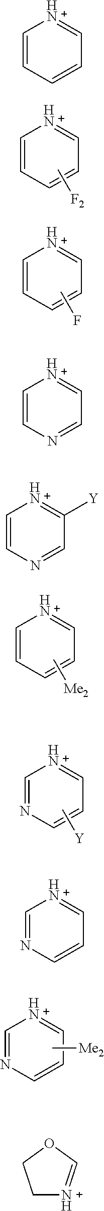

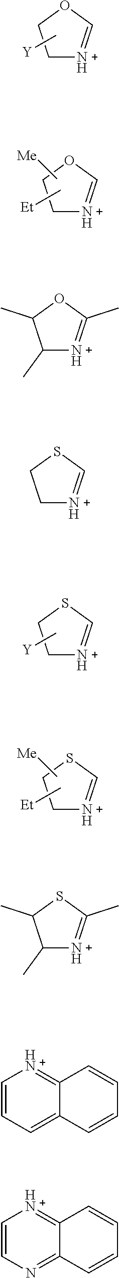

in which Y is alkyl, preferably, methyl or ethyl.

Other suitable cations can include onium cations. Suitable onium cations can include, for example, sulfonium and iodonium cations, for example, those of the following general Formula 12:

⁺X—(R¹⁰)s Formula 12

In Formula 12, X can be S or I, wherein when X is I then “a” can be 2, and when X is S then “a” can be 3. In Formula 12, R¹⁰ can be independently chosen from organic groups such as optionally substituted C₁₋₃₀ alkyl, polycyclic or monocyclic C₃₋₃₀ cycloalkyl, polycyclic or monocyclic C₆₋₃₀ aryl, or a combination thereof, wherein when X is S, two of the R groups together optionally form a ring.

For an SSA of an embodiment, example suitable sulfonium and iodonium cations include the following:

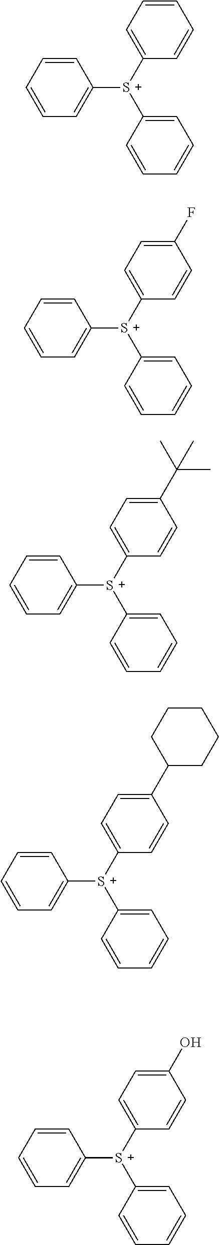 [SMILES: c1ccc([S+](c2ccccc2)c2ccccc2)cc1 ; Fc1ccc([S+](c2ccccc2)c2ccccc2)cc1 ; CC(C)(C)c1ccc([S+](c2ccccc2)c2ccccc2)cc1 ; c1ccc([S+](c2ccccc2)c2ccc(C3CCCCC3)cc2)cc1 ; Oc1ccc([S+](c2ccccc2)c2ccccc2)cc1]

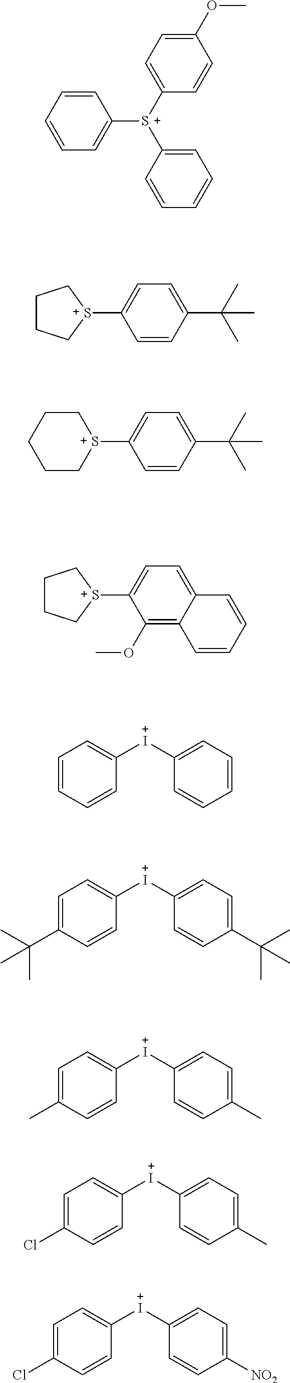

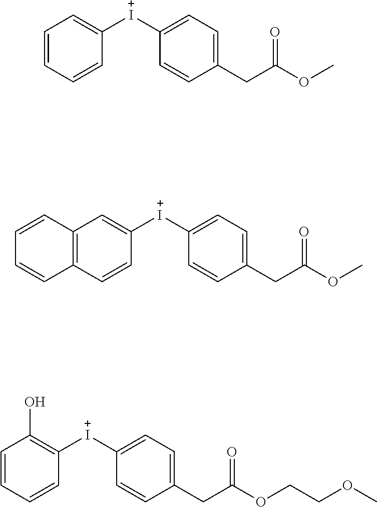 [SMILES: COC(=O)Cc1ccc([I+]c2ccccc2)cc1 ; COC(=O)Cc1ccc([I+]c2ccc3ccccc3c2)cc1 ; COCCOC(=O)Cc1ccc([I+]c2ccccc2O)cc1]

### Solubility Shifting Agent as Photoacid Generator (PAG)

For an SSA of an embodiment, suitable photoacid generators can include those capable of generating the acids described above.

### Solvents

In an embodiment of the present disclosure, the overcoat resist composition comprises an organic solvent that can include an organic solvent conventionally used in the manufacture of electronic devices.

When a first intermediate structure 11 is formed from a vinyl aromatic-based polymer, as is typical for KrF and EUV photoresists, and the resist can be developed as a PTD resist, the solvent can contain a solvent system including one or more nonpolar organic solvents. The term “nonpolar organic-based” can indicate that the solvent system includes greater than 50 wt % of combined nonpolar organic solvents based on total solvents of the composition, more typically greater than 70 wt %, greater than 85 wt % or 100 wt %, combined nonpolar organic solvents, based on total solvents of the composition. The nonpolar organic solvents can be typically present in the solvent system in a combined amount of from 70 to 98 wt %, preferably 80 to 95 wt %, more preferably from 85 to 98 wt %, based on the solvent system, for example.

In an embodiment, suitable nonpolar solvents can include, for example, ethers, hydrocarbons, and combinations thereof, with ethers being sometimes preferred. In an embodiment, suitable ether solvents can include, for example, alkyl monoethers and aromatic monoethers, particularly preferred of which can be those having a total carbon number of from 6 to 16. In an embodiment, suitable alkyl monoethers can include, for example, 1,4-cineole, 1,8-cineole, pinene oxide, di-n-propyl ether, diisopropyl ether, di-n-butyl ether, di-n-pentyl ether, diisoamyl ether, dihexyl ether, diheptyl ether, and dioctyl ether, with diisoamyl ether being preferred. In an embodiment, suitable aromatic monoethers can include, for example, anisole, ethylbenzyl ether, diphenyl ether, dibenzyl ether and phenetole, with anisole being preferred. In an embodiment, suitable aliphatic hydrocarbons can include, for example, n-heptane, 2-methylheptane, 3-methylheptane, 3, 3-dimethylhexane, 2,3,4-trimethylpentane, n-octane, n-nonane, n-decane, and fluorinated compounds such as perfluoroheptane. In an embodiment, suitable aromatic hydrocarbons can include, for example, benzene, toluene, and xylene.

In some embodiments, the solvent system can further include one or more alcohol and/or ester solvents. For certain compositions, an alcohol and/or ester solvent can provide enhanced solubility with respect to the solid components of the composition. In an embodiment, suitable alcohol solvents can include, for example: straight, branched or cyclic C₄₋₉ monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol, 4-octanol, 2,2,3,3,4,4-hexafluoro-1-butanol, 2,2,3,3,4,4,5,5-octafluoro-1-pentanol, and 2,2,3,3,4,4,5,5,6,6-decafluoro-1-hexanol; and C₅₋₉ fluorinated diols such as 2,2,3,3,4,4-hexafluoro-1,5-pentanediol, 2,2,3,3,4,4,5,5-octafluoro-1,6-hexanediol, or 2,2,3,3,4,4,5,5,6,6,7,7-dodecafluoro-1,8-octanediol. In an embodiment, an alcohol solvent can be preferably a C₄₋₉ monohydric alcohol, with 4-methyl-2-pentanol being preferred. In an embodiment, suitable ester solvents can include, for example, alkyl esters having a total carbon number of from 4 to 10, for example, alkyl propionates such as n-butyl propionate, n-pentyl propionate, n-hexyl propionate, and n-heptyl propionate, and alkyl butyrates such as n-butyl butyrate, isobutyl butyrate, and isobutyl isobutyrate. The one or more alcohol and/or ester solvents if used in a solvent system of an embodiment, can be typically present in a combined amount of from 2 to 50 wt %, more typically in an amount of from 2 to 30 wt %, based on the solvent system, for example.

In an embodiment, a solvent system for a developer can also include one or more additional solvents chosen, for example, from one or more of: ketones such as 2,5-dimethyl-4-hexanone and 2,6-dimethyl-4-heptanone; and polyethers such as dipropylene glycol monomethyl ether and tripropylene glycol monomethyl ether. Such additional solvents, if used, can be typically present in a combined amount of from 1 to 20 wt % based on the solvent system.

In an embodiment, when a first intermediate structure 11 is formed from a vinyl aromatic-based polymer, a preferred organic-based solvent system can include one or more monoether solvents in a combined amount of from 70 to 98 wt % based on the solvent system, and one or more alcohol and/or ester solvents in a combined amount of from 2 to 30 wt % based on the solvent system. The solvent system can be typically present in a developer in an amount of from 90 to 99 wt %, preferably from 95 to 99 wt %, based on the developer composition, for example. In an embodiment in which a first intermediate structure 11 is a NTD resist, a suitable organic solvent can include, but is not limit to, n-butyl acetate, 2-heptanone, propylene glycol methyl ether, propylene glycol methyl ether acetate, and combinations thereof, for example.

### Optional Components

In an embodiment of present disclosure, the overcoat resist composition may include optional components selected from the list of quenchers and optional components described above.

### Second Resist Composition

In an embodiment of present disclosure, a second resist composition may be used to form an overcoat resist layer 21. The second resist composition can include a second polymer, a solvent, and may also contain additional, optional components.

### Second Polymer

In an embodiment of present disclosure, a second polymer may be selected from the polymers described.

### Solvent

In an embodiment of present disclosure, a solvent for the overcoat resist composition may be selected from the solvents described above for the overcoat composition.

### Optional Components

In an embodiment of present disclosure, the overcoat resist composition may include optional components selected from the list of solubility shifting agents, quenchers, and optional components described above.

More example embodiments of the present disclosure are summarized here. Other embodiments can also be understood from the entirety of the specification as well as the claims filed herein.

Example 1. A method for forming a patterned mask, the method including: providing a first intermediate structure on a substrate, where the first intermediate structure includes a first material including a first polymer, where the first intermediate structure further includes a first converted region of a second material to a first depth into the first intermediate structure, where the second material has been chemically transformed from the first material by at least a catalyst portion of a first solubility shifting agent diffused into the first converted region, where the first material is insoluble in a developer containing a polar solvent, where the second material is soluble in the developer containing the polar solvent; providing a second intermediate structure on the substrate, where the second intermediate structure includes a third material including a second polymer with a functional group protected by a protecting group, where the second intermediate structure includes an overburden region overlying the first converted region of the first intermediate structure, where the third material is soluble in a solvent system that does not dissolve the first intermediate structure, where the third material is insoluble in the developer containing the polar solvent; and providing at least a catalyst portion of a second solubility shifting agent to the overburden region of the second intermediate structure and chemically transforming the overburden region of the second intermediate structure to a second converted region of a fourth material using the catalyst portion of the second solubility shifting agent as a chemical reaction catalyst, such that the fourth material is soluble in the developer containing the polar solvent.

Example 2. The method of example 1, where the protecting group is a vinyl ether protecting group.

Example 3. The method of example 2, where the vinyl ether protecting group includes an isobutyl vinyl ether, ethylhexyl vinyl ether, 2-ethylheptyl vinyl ether, cyclohexyl vinyl ether, octadecyl vinyl ether, or combinations thereof.

Example 4. The method of one of examples 1 to 3, where the developer is an aqueous base.

Example 5. The method of example 4, where the developer is an aqueous tetramethylammonium hydroxide (TMAH) developer.

Example 6. The method of one of examples 1 to 5, where the functional group is a hydroxyl group.

Example 7. The method of one of examples 1 to 6, where the second polymer includes styrene, para-hydroxystyrene, an acrylate, a methacrylate, norbornene, or any combination thereof.

Example 8. The method of example 7, where the second polymer includes para-hydroxystyrene.

Example 9. The method of example 8, where the second polymer further includes styrene and one or more of tert-butyl acrylate and n-butyl acrylate.

Example 10. The method of one of examples 8 and 9, where the functional group is a hydroxyl group of the para-hydroxystyrene.

Example 11. The method of one of examples 1 to 10, where the second solubility shifting agent is selected such that it will not affect the first intermediate structure.

Example 12. The method of one of examples 1 to 11, where the first solvent system contains a nonpolar organic solvent.

Example 13. The method of one of examples 1 to 12, where the second solubility shifting agent is the first solubility shifting agent, and where providing at least the catalyst portion of the second solubility shifting agent to the overburden region includes: diffusing at least the catalyst portion of the first solubility shifting agent from the second material into the overburden region of the second intermediate structure and chemically transforming the overburden region of the second intermediate structure to the second converted region of the fourth material.

Example 14. The method of one of examples 1 to 13, where the third material of the second intermediate structure includes the second solubility shifting agent, and where providing at least the catalyst portion of the second solubility shifting agent to the overburden region includes: generating the catalyst portion of the second solubility shifting agent in the overburden region of the second intermediate structure by activating the second solubility shifting agent and chemically transforming the overburden region of the second intermediate structure to the second converted region of the fourth material.

Example 15. The method of example 14, where activating the second solubility shifting agent in the overburden region also activates the second solubility shifting agent in other regions of the second intermediate structure to chemically transform the other regions of the second intermediate structure to converted regions of the fourth material, and where the dissolution rate of the fourth material in the developer is less than the dissolution rate of the second material in the developer.

Example 16. A method for forming a patterned mask, the method including: providing a first intermediate structure on a substrate, where the first intermediate structure includes a first material including a first polymer, where the first intermediate structure further includes a first converted region of a second material to a first depth into the first intermediate structure, where the second material has been chemically transformed from the first material by at least a catalyst portion of a first solubility shifting agent diffused into the first converted region, where the first material is insoluble in an aqueous tetramethylammonium hydroxide (TMAH) developer, where the second material is soluble in the aqueous TMAH developer; providing a second intermediate structure on the substrate, where the second intermediate structure includes a third material including a second polymer, where the second polymer includes para-hydroxystyrene, where a hydroxyl group of the para-hydroxystyrene is protected by a vinyl ether protecting group, where the second intermediate structure includes an overburden region overlying the first converted region of the first intermediate structure, where the third material is soluble in a solvent system that does not dissolve the first intermediate structure, where the third material is insoluble in the an aqueous TMAH developer; and providing at least a catalyst portion of a second solubility shifting agent to the overburden region of the second intermediate structure and chemically transforming the overburden region of the second intermediate structure to a second converted region of a fourth material using the catalyst portion of the second solubility shifting agent as a chemical reaction catalyst, such that the fourth material is soluble in the aqueous TMAH developer.

Example 17. The method of example 16, where the second solubility shifting agent is the first solubility shifting agent, and where providing at least the catalyst portion of the second solubility shifting agent to the overburden region includes: diffusing at least the catalyst portion of the first solubility shifting agent from the second material into the overburden region of the second intermediate structure and chemically transforming the overburden region of the second intermediate structure to the second converted region of the fourth material.

Example 18. The method of one of examples 16 and 17, where the third material of the second intermediate structure includes the second solubility shifting agent, and where providing at least the catalyst portion of the second solubility shifting agent to the overburden region includes: generating the catalyst portion of the second solubility shifting agent in the overburden region of the second intermediate structure by activating the second solubility shifting agent in the overburden region and chemically transforming the overburden region of the second intermediate structure to the second converted region of the fourth material.

Example 19. The method of one of examples 16 to 18, where the second polymer further includes styrene and one or more of tert-butyl acrylate and n-butyl acrylate.

Example 20. A method for forming a patterned mask, the method including: providing a patterned photoresist layer on a substrate, where the patterned photoresist layer includes a first material including a first polymer, where the first material is insoluble in a developer containing a polar solvent; depositing an overcoat layer over the patterned photoresist layer and the substrate, where the overcoat layer includes a first solubility shifting agent; diffusing at least a catalyst portion of the first solubility shifting agent from the overcoat layer into first regions of the patterned photoresist layer and chemically transforming the first regions of the patterned photoresist layer to anti-spacer regions of a second material to a first depth into the patterned photoresist layer, where the second material is soluble in the developer containing the polar solvent; removing the overcoat layer leaving behind the patterned photoresist layer including the anti-spacer regions; depositing an additional resist layer over the patterned photoresist layer, where the additional resist layer includes a third material including a second polymer with a functional group protected by a protecting group, where the additional resist layer includes overburden regions overlying the anti-spacer regions of the patterned photoresist layer, where the third material is soluble in a solvent system that does not dissolve the patterned photoresist layer, where the third material is insoluble in the developer containing the polar solvent; chemically transforming the overburden regions of the additional resist layer to a soluble region of a fourth material using a chemical reaction catalyst, such that the fourth material is soluble in the developer containing the polar solvent by diffusing at least a catalyst portion of the first solubility shifting agent as the chemical reaction catalyst from the anti-spacer regions of the first patterned photoresist layer into the overburden regions, or generating a catalyst portion of a second solubility shifting agent in the overburden region of the second intermediate structure as the chemical reaction catalyst by activating the second solubility shifting agent; and removing the anti-spacer regions using the polar solvent of the developer to form an anti-spacer pattern including remaining portions of the first patterned photoresist layer and the additional resist layer having openings to the substrate corresponding to the anti-spacer regions, where at least part of the openings has a critical dimension corresponding to the first depth.

While illustrative and example embodiments have been described with reference to illustrative drawings, this description is not intended to be construed in a necessarily limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

What is claimed is:

1. A method for forming a patterned mask, the method comprising:
providing a first intermediate structure on a substrate, wherein the first intermediate structure comprises a first material comprising a first polymer,
wherein the first intermediate structure further comprises a first converted region of a second material to a first depth into the first intermediate structure, wherein the second material has been chemically transformed from the first material by at least a catalyst portion of a first solubility shifting agent diffused into the first converted region,
wherein the first material is insoluble in a developer containing a polar solvent,
wherein the second material is soluble in the developer containing the polar solvent;
providing a second intermediate structure on the substrate, wherein the second intermediate structure comprises a third material comprising a second polymer with a functional group protected by a protecting group,
wherein the second intermediate structure comprises an overburden region overlying the first converted region of the first intermediate structure,
wherein the third material is soluble in a solvent system that does not dissolve the first intermediate structure,
wherein the third material is insoluble in the developer containing the polar solvent; and
providing at least a catalyst portion of a second solubility shifting agent to the overburden region of the second intermediate structure and chemically transforming the overburden region of the second intermediate structure to a second converted region of a fourth material using the catalyst portion of the second solubility shifting agent as a chemical reaction catalyst, such that the fourth material is soluble in the developer containing the polar solvent.

2. The method of claim 1, wherein the protecting group is a vinyl ether protecting group.

3. The method of claim 2, wherein the vinyl ether protecting group comprises an isobutyl vinyl ether, ethylhexyl vinyl ether, 2-ethylheptyl vinyl ether, cyclohexyl vinyl ether, octadecyl vinyl ether, or combinations thereof.

4. The method of claim 1, wherein the developer is an aqueous base.

5. The method of claim 4, wherein the developer is an aqueous tetramethylammonium hydroxide (TMAH) developer.

6. The method of claim 1, wherein the functional group is a hydroxyl group.

7. The method of claim 1, wherein the second polymer comprises styrene, para-hydroxystyrene, an acrylate, a methacrylate, norbornene, or any combination thereof.

8. The method of claim 7, wherein the second polymer comprises para-hydroxystyrene.

9. The method of claim 8, wherein the second polymer further comprises styrene and one or more of tert-butyl acrylate and n-butyl acrylate.

10. The method of claim 8, wherein the functional group is a hydroxyl group of the para-hydroxystyrene.

11. The method of claim 1, wherein the second solubility shifting agent is selected such that it will not affect the first intermediate structure.

12. The method of claim 1, wherein the first solvent system contains a nonpolar organic solvent.

13. The method of claim 1, wherein the second solubility shifting agent is the first solubility shifting agent, and wherein providing at least the catalyst portion of the second solubility shifting agent to the overburden region comprises:
diffusing at least the catalyst portion of the first solubility shifting agent from the second material into the overburden region of the second intermediate structure and chemically transforming the overburden region of the second intermediate structure to the second converted region of the fourth material.

14. The method of claim 1, wherein the third material of the second intermediate structure comprises the second solubility shifting agent, and wherein providing at least the catalyst portion of the second solubility shifting agent to the overburden region comprises:
generating the catalyst portion of the second solubility shifting agent in the overburden region of the second intermediate structure by activating the second solubility shifting agent and chemically transforming the overburden region of the second intermediate structure to the second converted region of the fourth material.

15. The method of claim 14, wherein activating the second solubility shifting agent in the overburden region also activates the second solubility shifting agent in other regions of the second intermediate structure to chemically transform the other regions of the second intermediate structure to converted regions of the fourth material, and wherein the dissolution rate of the fourth material in the developer is less than the dissolution rate of the second material in the developer.

16. A method for forming a patterned mask, the method comprising:
providing a first intermediate structure on a substrate, wherein the first intermediate structure comprises a first material comprising a first polymer,
wherein the first intermediate structure further comprises a first converted region of a second material to a first depth into the first intermediate structure, wherein the second material has been chemically transformed from the first material by at least a catalyst portion of a first solubility shifting agent diffused into the first converted region,
wherein the first material is insoluble in an aqueous tetramethylammonium hydroxide (TMAH) developer,
wherein the second material is soluble in the aqueous TMAH developer;
providing a second intermediate structure on the substrate, wherein the second intermediate structure comprises a third material comprising a second polymer, wherein the second polymer comprises para-hydroxystyrene, wherein a hydroxyl group of the para-hydroxystyrene is protected by a vinyl ether protecting group,
wherein the second intermediate structure comprises an overburden region overlying the first converted region of the first intermediate structure,
wherein the third material is soluble in a solvent system that does not dissolve the first intermediate structure,
wherein the third material is insoluble in the an aqueous TMAH developer; and
providing at least a catalyst portion of a second solubility shifting agent to the overburden region of the second intermediate structure and chemically transforming the overburden region of the second intermediate structure to a second converted region of a fourth material using the catalyst portion of the second solubility shifting agent as a chemical reaction catalyst, such that the fourth material is soluble in the aqueous TMAH developer.

17. The method of claim 16, wherein the second solubility shifting agent is the first solubility shifting agent, and wherein providing at least the catalyst portion of the second solubility shifting agent to the overburden region comprises:
diffusing at least the catalyst portion of the first solubility shifting agent from the second material into the overburden region of the second intermediate structure and chemically transforming the overburden region of the second intermediate structure to the second converted region of the fourth material.

18. The method of claim 16, wherein the third material of the second intermediate structure comprises the second solubility shifting agent, and wherein providing at least the catalyst portion of the second solubility shifting agent to the overburden region comprises:
generating the catalyst portion of the second solubility shifting agent in the overburden region of the second intermediate structure by activating the second solubility shifting agent in the overburden region and chemically transforming the overburden region of the second intermediate structure to the second converted region of the fourth material.

19. The method of claim 16, wherein the second polymer further comprises styrene and one or more of tert-butyl acrylate and n-butyl acrylate.

20. A method for forming a patterned mask, the method comprising:
providing a patterned photoresist layer on a substrate, wherein the patterned photoresist layer comprises a first material comprising a first polymer,
wherein the first material is insoluble in a developer containing a polar solvent;
depositing an overcoat layer over the patterned photoresist layer and the substrate, wherein the overcoat layer comprises a first solubility shifting agent;
diffusing at least a catalyst portion of the first solubility shifting agent from the overcoat layer into first regions of the patterned photoresist layer and chemically transforming the first regions of the patterned photoresist layer to anti-spacer regions of a second material to a first depth into the patterned photoresist layer,
wherein the second material is soluble in the developer containing the polar solvent;
removing the overcoat layer leaving behind the patterned photoresist layer including the anti-spacer regions;
depositing an additional resist layer over the patterned photoresist layer, wherein the additional resist layer comprises a third material comprising a second polymer with a functional group protected by a protecting group,
wherein the additional resist layer comprises overburden regions overlying the anti-spacer regions of the patterned photoresist layer,
wherein the third material is soluble in a solvent system that does not dissolve the patterned photoresist layer,
wherein the third material is insoluble in the developer containing the polar solvent;
chemically transforming the overburden regions of the additional resist layer to a soluble region of a fourth material using a chemical reaction catalyst, such that the fourth material is soluble in the developer containing the polar solvent by
diffusing at least a catalyst portion of the first solubility shifting agent as the chemical reaction catalyst from the anti-spacer regions of the first patterned photoresist layer into the overburden regions, or
generating a catalyst portion of a second solubility shifting agent in the overburden region of the second intermediate structure as the chemical reaction catalyst by activating the second solubility shifting agent; and
removing the anti-spacer regions using the polar solvent of the developer to form an anti-spacer pattern comprising remaining portions of the first patterned photoresist layer and the additional resist layer having openings to the substrate corresponding to the anti-spacer regions, wherein at least part of the openings has a critical dimension corresponding to the first depth.
